(19) United States
(12) Patent Application Publication
(10) Pub. No.: US 2024/0272099 A1
(43) Pub. Date: Aug. 15, 2024

(54) HIGH RESOLUTION, LOW ENERGY ELECTRON MICROSCOPE FOR PROVIDING TOPOGRAPHY INFORMATION AND METHOD OF MASK INSPECTION

(71) Applicant: Carl Zeiss SMT GmbH, Oberkochen (DE)

(72) Inventors: Daniel Schwarz, Aalen (DE); Michael Schnell, Rechberghausen (DE); Nicole Auth, Gustavsburg (DE)

(21) Appl. No.: 18/631,733

(22) Filed: Apr. 10, 2024

Related U.S. Application Data
(63) Continuation of application No. PCT/EP2022/079753, filed on Oct. 25, 2022.

(30) Foreign Application Priority Data
Oct. 28, 2021 (DE) 102021212203.5

(51) Int. Cl. G01N 23/203; G01N 23/20058; H01J 37/147; H01J 37/21; H01J 37/244; H01J 37/28; H01J 37/30; H01L 21/67

(52) U.S. Cl. CPC G01N 23/203; G01N 23/20058; H01J 37/147; H01J 37/21; H01J 37/244; H01J 37/28; H01L 21/67288; G01N 2223/401; G01N 2223/6116; G01N 2223/6462; H01J 37/30; H01J 2237/24475; H01J 2237/2814

(57) ABSTRACT

A corrected scanning electron microscope (CSEM) and a method of operating the CSEM for selectively separating a material contrast from a topography contrast is presented. The microscope and the method enable high imaging resolution with backscattered electrons generated from low energy primary electrons. The CSEM and the method is applicable to mask repair and circuit editing processes with resolution requirements in the low nm range or even below.

### CROSS-REFERENCE TO RELATED APPLICATIONS

This application is a continuation of and claims priority under 35 U.S.C. § 120 from PCT Application No. PCT/EP2022/079753, filed on Oct. 25, 2022, which claims priority from German Application No. 10 2021 212 203.5, filed on Oct. 28, 2021. The entire contents of each of these priority applications are incorporated herein by reference.

### TECHNICAL FIELD

The invention provides a scanning electron microscope with means for separating topography information from material contrast in low energy, high resolution imaging. The invention is especially applicable for inspection or monitoring of semiconductor fabrication processes, for example for semiconductor wafer inspection and for high precision metrology applications such as mask inspection and mask repair.

### BACKGROUND

Requirements for semiconductor inspection, mask inspection and mask repair are becoming more and more demanding. With the actual and future critical dimensions (CD) below 5 nm, below 3 nm and even below 1 nm, also the placement of the semiconductor features becomes more and more demanding. The pattern placement is typically correlated with the overlay requirement, which is typically specified by a fraction of the CD, for example ⅓ or less of the CD.

Semiconductor masks typically have a topography formed by the absorbing structures on top of the mask material. Absorbing structures are typically formed by lithographic processing of an opaque film, for example a chrome film of up to a thickness of tens of nm. Other materials or structures can be employed as well, for example for phase shift masks. For EUV masks, also other absorbers can be employed as for example thin tantalum films or silicon nitride. For the high requirements for resolution and pattern or edge placement, topography effects become more and more limiting in mask inspection and repair applications.

The computer designed patterns of a lithography mask typically have feature sizes comparable to the feature sizes or CD to be produced on a wafer. Therefore, especially for EUV masks, features sizes of patterns such as assist features for example for OPC (optical proximity correction) are becoming smaller, for example below 10 nm, below 5 nm, or even below 3 nm. The precision of the pattern placement by optical image formation by optical lithography is theoretically unlimited, but it is practically limited for example by the accuracy of the edge placement of features on the lithography masks. The placement of the edges of mask patterns must therefore be very well controlled within the overlay requirement of the lithography process of for example below 3 nm or even below 1 nm, for example even about 0.1 nm.

During semiconductor manufacturing, the requirements for resolution and accuracy are increasing in the same order. Typically, wafers are planarized frequently during the fabrication steps to avoid any topography effects generated for example by structured layer deposition, oxidation, doping or etching. However, some fabrication process steps require inspection of the topography of the almost planar features produced on the wafer with increasing accuracy.

The effects of the topography of features during wafer fabrication and of the mask structure are limiting the accuracy of conventional imaging techniques. The imaging technique currently employed is backscattered or secondary electron collection by scanning electron microscopy. The surface of a sample, for example a wafer or a mask surface, is raster scanned by a narrowly focused primary electron beam. The secondary and backscattered electrons are collected, and the intensity is evaluated. Some means might be employed to select certain energy regimes or angular spectra of the collected electrons. However, with the increased requirements, the resolution and accuracy of the imaging techniques currently employed are not enough anymore. Even shallow mask layers of few tens of nm start to show shadowing effects for the backscattered electrons. The form and slope angle of the edges of features have an impact on the backscattered electron signal, which is in the order of the required imaging accuracy.

In a conventional scanning electron microscope (SEM), the image intensity is typically recorded by fixed in-lens detectors at different positions. Examples of such a conventional SEM are described in U.S. Pat. No. 7,910,887 B2 or in U.S. Pat. No. 10,720,304 B2. The in-lens detectors are sometimes called ESB-detectors for energy selective collection of backscattered electrons. Each detector records electrons of different take-off angle or energy. The elastically backscattered electrons emitted under a higher angle typically contain more topography information, while the electrons emitted close to the optical axis of the microscope contain mostly material information. In systems as described in U.S. Pat. No. 10,720,304 B2, the primary electrons are passing the in-lens detectors at a central aperture of the detector. Inside of this aperture, secondary or backscattered electrons cannot be detected. Therefore, the information of backscattered electrons at low scattering angles is lost. The loss of information becomes increasingly limiting for low energy electrons. At lower kinetic energy of the primary electrons, generally the scattering angles are virtually reduced, and more off-axis electrons are collected, while electrons emitted at the low and medium angles are lost. EP 2,463,889 B1 describes a moveable diaphragm aperture in between the in-lens and ESB detectors to limit the phase space of backscattered electrons. Such a solution is not enough for the specification requirements described above and does not allow to access the off-axis parts of the backscattered electron's momentum distribution. Further, since the aperture needs to float on high potential (for example the liner-tube potential), a moving aperture is difficult to implement. In addition, mechanical movement does not allow a fast change of the operation mode for a fast image acquisition.

For high resolution requirements, for example during an electron beam assisted repair operation, low energy electron microscopy is required with kinetic energies of the electrons below several 100 eV, for example below 500 ev, below 300 eV or even below. It has therefore been proposed to apply a corrected low energy microscope, utilizing an imaging system for imaging the backscattered electrons via a beam separator to a detector. Such systems are for example disclosed in U.S. Pat. Nos. 6,855,939, 8,592,776 B2 and DE 10 2019 214 936 A1. However, while these systems are configured to separate for example low energy secondary electrons from backscattered electrons, topography information from the backscattered electrons is not considered. However, for lower kinetic energy with the reduced angular spread of the collected backscattered electrons, an increasingly larger fraction of the backscattered electrons comprises topography information, which deteriorates the measurement accuracy of the corrected low energy microscopes of the prior art. Furthermore, material contrast information is lost and process control applications which require a material contrast cannot be performed with sufficient accuracy anymore.

It is therefore a task of the present invention to provide a high-resolution inspection system for semiconductor wafers or masks, which is capable of extracting or separating the entangled topography information from the material information from the backscattered electrons. It is a further task of the invention to provide a method of high-resolution mask or semiconductor inspection under consideration of topography or edge effects of structures layer features of semiconductors or masks with higher accuracy and higher precision. It is a further task of the invention to provide a precise monitoring system for monitoring a mask repair operation complying with the current and future requirements for semiconductor masks. It is further a task of the invention to provide a method for a fast and reliable semiconductor or mask inspection in presence of topography effects and a system which can be configured for a fast and reliable semiconductor or mask inspection in presence of topography effects.

### SUMMARY

The invention which solves the tasks is described by the independent claims. Further examples of embodiments are described in the dependent claims.

The invention enables the application of a low-energy electron imaging for the investigating of a surface (25) of a sample (7) with a primary electron beam with a low landing energy LE. A low-energy electron microscope (1) according to an embodiment is comprising a beam forming unit (1400), configured for generating during use the corrected primary electron beam (3). The primary electron beam (3) is pre-corrected with the correction means of the beam forming unit (1400) and focused by a primary beam focusing unit (1100) onto the surface (25) of the sample (7). The beam forming unit (1400) and the primary beam focusing unit (1100) are configured to focus the corrected primary electron beam (3) on the surface (25) of the sample (7) and to decelerate the primary electron beam (3) before reaching the sample surface (25). Thereby, low landing energies of primary electrons with kinetic energies below 400 eV, preferable below 300 eV, even more preferably below 200 eV, or even more preferably below 150 eV can be achieved at a high imaging resolution of below 3 nm, preferably below 2 nm or even below.

The primary beam focusing unit (1100) is further configured for collecting during use a backscattered electron beam (9) comprising electrons which are scattered at large angles from the surface (25) of the sample (7). The large angles of the collected backscattered electrons typically exceeding 0.7 rad and are preferably up to 1.3 rad from the normal of the surface (25) of the sample (7). The low-energy electron microscope (1) further comprises a detection unit (1600) with at least a first confined detector segment (1801) for detecting at least a first segment of the angular spectrum of the backscattered electron beam (9) and for generating at least a first detection signal I1. The low-energy electron microscope (1) further comprises a beam dividing unit (1500) for guiding during use the corrected primary charged particle beam (3) from the beam forming unit (1400) to the primary beam focusing unit (1100) and for guiding the backscattered electron beam (9) from the primary beam focusing unit (1100) to the detection unit (1600). The backscattered electron beam thereby includes an axial segment of the angular spectrum of the backscattered electron beam (9), which propagates parallel and in opposite direction to the corrected primary charged particle beam (3). The detection unit (1600) further comprises an adjustment element and is connected to a control unit (800). The control unit (800) is configured to control the adjustment element to select in a first imaging mode the first selected segment of the angular spectrum of the backscattered electron beam (9). The adjustment element comprises at least one of a deflection unit (1603) configured for deflecting the backscattered electron beam (9), a focusing lens (1605) configured for focusing the backscattered electron beam (9), an adjustable energy filter (1607) to block backscattered electrons below a kinetic energy threshold of an adjustable dispersing unit (1611) to distribute the backscattered electron beam (9) according to a kinetic energy. In an example, the control unit (800) is configured to control the deflection unit (1603) to select an off-axis segment of the angular spectrum corresponding to backscattered electrons (9) scattered at large angles from the surface (25) of the sample (7). In an example, the control unit (800) is configured to control the focusing lens (1605) to select a larger segment of the angular spectrum corresponding to backscattered electrons (9) scattered at a larger angular range from the surface (25) of the sample (7). In an example, the control unit (800) is configured to control the focusing lens (1605) to select a smaller segment of the angular spectrum corresponding to backscattered electrons (9) scattered at a narrow angular range from the surface (25) of the sample (7). Thereby, different segments of the angular spectrum of the backscattered electron beam (9) can be selected. In an example, the control unit (800) is further configured to control the adjustment element to select in a second imaging mode a second selected segment of the angular spectrum of the backscattered electron beam (9), different from the first selected segment. The control unit (800) may be configured to sequentially perform a first image scan of a segment of the surface (25) of the sample (7) in the first imaging mode and to perform a second image scan at the same segment of the surface (25) in the second imaging mode.

In an example, the detection unit (1600) can comprise a second confined detector segment (1802) to generate during use a second detection signal I2 corresponding to a second selected segment of the angular spectrum of the backscattered electron beam (9).

The control unit (800) is further configured to determine at least one of an edge position of a layer edge, a feature dimension, an edge roughness; an edge slope; or a micro-defect with an accuracy below 2 nm, preferable below 1 nm, even more preferably below 0.5 nm. The high resolution is achieved by utilizing primary electrons of low landing energy and the correction means of the low-energy electron microscope (1). The unambiguous determination of edge positions, edge slopes and micro-defects is achieved by a separation of topography effects from a material contrast of the segment of the surface (25) of the mask or wafer (7). The separation is achieved by the control of the operation of the detection unit (1600) in at least first and second imaging modes, comprising the detection of different segments of the angular spectrum of the backscattered electron beam (9). As correction means, the low energy electron microscope (1) comprises for example an electrostatic mirror corrector (1415).

In an example, the control unit (800) is configured to determine the at least first and second imaging modes suitable for a detection and an extraction of a topography effect, and for separation of topography effects from a material contrast of the segment of the surface (25) of the mask or wafer (7).

In a further embodiment, the low energy electron microscope (1) comprises a beam forming unit (1400), a primary beam focusing unit (1100), a detection unit (1600) with a first confined detector segment (1801), and a beam dividing unit (1500). The detection unit (1600) further comprises at least a second confined detector segment (1801) for detecting at least a second segment of an angular spectrum of a backscattered electron beam (9) and for generating at least a second detection signal I2, different from a first detection signal I1. The beam forming unit (1400) is configured for generating during use a corrected primary charged particle beam (3). The beam forming unit (1400) and the primary beam focusing unit (1100) are configured to focus the corrected primary electron beam (3) on the surface (25) of the sample (7) and to decelerate the primary electron beam (3) before reaching the sample surface (25) to kinetic energies below 400 eV, preferable below 300 eV, even more preferably below 200 eV, or even more preferably below 150 eV. The primary beam focusing unit (1100) is further configured for collecting during use the backscattered electron beam (9) comprising electrons which are scattered at large angles exceeding 0.7 rad, preferably of up to 1.3 rad relative to the normal of the surface (25) of the sample (7).

The beam dividing unit (1500) is configured for guiding during use a corrected primary charged particle beam (3) from the beam forming unit (1400) to the primary beam focusing unit (1100) and for guiding a backscattered electron beam (9) from the primary beam focusing unit (1100) to the detection unit (1600). The backscattered electron beam (9) includes an axial segment of the angular spectrum of the backscattered electron beam (9), which propagates parallel and in opposite direction to the corrected primary charged particle beam (3).

The first confined detector segment (1801) is configured for detecting a first segment of the angular spectrum of the backscattered electron beam (9) and for generating a first detection signal I1. In an example, the detection unit (1600) comprises a third or further confined detector segment (1802) to generate during use a third or further detection signal I3 corresponding to a third of further selected segment of the angular spectrum of the backscattered electron beam (9). Thus, a plurality of at least two detector segments is configured to select a plurality of different detection signals corresponding to different segments of the angular spectrum of the backscattered electron beam (9). A control unit (800) of the low energy electron microscope (1) is further configured to determine form the at least first and second detection signal I1 and I2 at least one of an edge position of a layer edge, a feature dimension, an edge roughness, an edge slope, or a micro-defect, with an accuracy below 2 nm, preferably below 1 nm, even more preferably below 0.5 nm. The high resolution is achieved by utilizing primary electrons of low landing energy and the correction means of the low-energy electron microscope (1). The unambiguous determination of edge positions, edge slopes and micro-defects is achieved by a separation of topography effects from a material contrast of the segment of the surface (25) of the mask or wafer (7). The separation is achieved by the at least first and second detection signal I1 and I2 corresponding to different segments of the angular spectrum of the backscattered electron beam (9). As correction means, the low energy electron microscope (1) comprises for example an electrostatic mirror corrector (1415).

According to a further aspect of the invention, an apparatus (1000) for inspection, repair or editing of a mask or wafer is given. The apparatus comprises low-energy electron microscope (1) described in the embodiments above. In the low energy mode, a low-energy electron microscope (1) is configured to focus the corrected primary electron beam (3) on the surface (25) of the mask or wafer (7) with low kinetic energy of the primary electrons below 400 eV, preferable below 300 eV, even more preferably below 200 eV, or even more preferably below 150 eV. The low-energy electron microscope (1) is further configured to collect backscattered electrons at large angles exceeding 0.7 rad, preferably of up to 1.3 rad from the normal of the surface (25) of the sample (7). A beam dividing unit (1500) of the low-energy electron microscope (1) is configured for dividing during use the corrected primary charged particle beam (3) from the backscattered electron beam (9). The low-energy electron microscope (1) is configured to collect and image during use the backscattered electron beam (9) including an axial segment of the angular spectrum of the backscattered electron beam (9), which is propagating parallel and in opposite direction to the corrected primary charged particle beam (3).

A detection unit (1600) of the low-energy electron microscope (1) comprises at least an adjustment element. A control unit (800) of the apparatus (1000) connected to a detection unit (1600) is configured to perform an inspection task of a segment of the surface (25) of the sample (7), for example a mask or a wafer. A detection unit (1600) with at least a first confined detector segment (1801) is configured to selectively detect at least a first selected segment of the angular spectrum of the backscattered electron beam (9) with the at least first confined detector segment (1801) to generate at least a first detection signal I1. The detection unit (1600) is further configured to selectively detect a second selected segment of the angular spectrum of the backscattered electron beam (9) to generate at least a second detection signal I2, wherein the second selected segment of the angular spectrum is different from the first selected segment of the angular spectrum of the backscattered electron beam (9). The control unit (800) is configured to control the adjustment element to selectively detect the at least first and/or second signals I1 and/or I2. The adjustment element comprises at least one of a deflection unit (1603), a focusing lens (1605), an adjustable energy filter (1607) or an adjustable dispersing unit (1611). In an example, the control unit (800) is configured to select a single, off axis segment of the angular spectrum and to perform the inspection task with the single off axis segment of the angular spectrum.

In an example, the control unit (800) selects the at least first and/or second selected segment of the angular spectrum of the backscattered electron beam (9) based on predetermined information about a structure on the surface (25) of the sample (7). The structure can be an absorber layer on a mask or a conductor line in wafer and can comprise an edge or a dimension.

In an example, the control unit (800) is configured to sequentially adjust the detection unit (1600) in a first imaging mode to collect at least the first signal I1 and to adjust the detection unit (1600) in a second imaging mode to collect at least a further signal in a subsequent second image scan across the surface (25) of the sample (7).

In an example, the detection unit (1600) comprises at least a second confined detector segment (1802) to generate during use at least a second or further detection signal I2 corresponding to a second or further selected segment of the angular spectrum of the backscattered electron beam (9) in a single image scan across the surface (25) of the sample (7). The detection unit (1600) may further comprise an adjustment element, wherein the control unit (800) is configured to control the adjustment element to selectively detect the at least first and second selected segment of the angular spectrum of the backscattered electron beam (9). The apparatus (1000) with the detection unit (1600) comprising at least two detector segments may further be configured to detect first and second detection signal in a first single image scan across the surface (25) of the sample (7) and to detect third and further image signals corresponding to third and further selected segments of the angular spectrum of the backscattered electron beam (9) in a second single image scan across the surface (25) of the sample (7) at the same inspection position.

In an example, the first selected segment of the angular spectrum of the backscattered electron beam (9) is selected to generate a first detection signal I1 with a reduced sensitivity to the topography of the segment of the surface (25), and the second selected segment of the angular spectrum of the backscattered electron beam (9) is selected to generate a second detection signal I2 with an increased sensitivity to the topography of the segment of the surface (25). Thereby, topography information can be separated from material contrast and for example a position of a layer edge or a slope of a layer edge can be determined with high precision. The apparatus according to the embodiment further comprises a plurality of gas nozzles (152) for providing a plurality of process gases to a surface (25) of a sample (7). The control unit (800) is configured to perform during use at least one of an electron-beam assisted deposition or electron-beam assisted etching operation. The control unit (800) is further configured to initiate or terminate an electron-beam assisted repair or editing process based on the at least a first detection signal I1 and/or second detection signal I2.

According to a further embodiment of the invention, a method of inspection, repair or circuit edit of a mask or wafer with high resolution below 2 nm, preferable below 1 nm, even more preferably below 0.5 nm is presented. The method comprises the alignment of an inspection site of a mask or wafer (7) in an image plane (101) of a low-energy electron microscope (1). The method further comprises the selection of at least a first imaging mode and a second imaging mode suitable for a detection and an extraction of topography effects, and for separation of topography effects from a material contrast of the surface segment of the mask or wafer (7) at the inspection site. The method further comprises a first image scan with low landing energies of a primary electron beam (3) in the first imaging mode to acquire a first image signal and a second image scan with low landing energies of the primary electron beam (3) in the second imaging mode to acquire a second image signal. According to the method, the first and second image signals are analyzed and a topography information and a material composition of the surface segment of the mask or wafer (7) at the inspection site is derived. In an example, during an image scan, a first signal is generated to drive an adjustment element of a detection unit (1600) for deflecting and/or focusing of the backscattered electron beam (9). Thereby, a first selected segment of the angular spectrum of the backscattered electron beam (9) is detected in the first imaging mode. In an example, a second signal is generated to drive an adjustment element of a detection unit (1600) for deflecting and/or focusing of the backscattered electron beam (9). Thereby, a second selected segment of the angular spectrum of the backscattered electron beam (9) is detected in the second imaging mode. The method further comprises the determination of at least one of a minimum intensity (927), a maximum intensity (929), a width or extension of a shadow region dx, a minimum intensity position Mx, and/or a slope (935) of an image signal at layer edge; or a difference of at least one of the values above between the first and second detection signal. Thereby, at least one of an edge position of a layer edge, a feature dimension, an edge roughness, an edge slope, or a micro-defect can be determined with an accuracy below 2 nm, preferable below 1 nm, even more preferably below 0.5 nm. The determination can be achieved for example by a comparison to predetermined detection signals of by model-based simulation of a detection result. According to an example, the method further comprises the application of a machine learning algorithm with a set of training or reference data corresponding to a plurality of detection signals of at least one of an edge position of a layer edge, a feature dimension, an edge roughness, an edge slope, or a micro-defect. During the application at different inspection sites, the method may further receive predetermined information about an inspection site of the mask or wafer (7) and the selection of at least a at least first imaging mode and a second imaging mode can be performed according to the predetermined information. The predetermined information can comprise the orientation of a layer edge, a feature orientation, a material composition, a height information, or other topography information or information about material compositions.

In an example, the method comprises the step of determining and storing the at least first and second imaging mode suitable for a detection and an extraction of topography effects, and for separation of topography effects from a material contrast of the surface segment of the mask or wafer (7) at the inspection site. During the determination of the ideal imaging modes, a sequence of at least two image scans with low landing energies of a primary electron beam (3) are performed, each with a different selected segment of the angular spectrum of the backscattered electron beam (9) at the inspection site. From the detection signals of the sequence, the at least first and second imaging mode is derived. For example, an orientation of a layer edge is derived, or a height of a layer edge, and a deflection angle of the deflection unit is determined according to the orientation and the height of the layer edge. The at least first and second imaging mode is stored in a memory for inspection tasks at a subsequent similar inspection site of the mask or wafer.

According to a further example, the at least first and second imaging mode suitable for a detection and an extraction of topography effects, and for separation of topography effects from a material contrast of the surface segment of the mask or wafer (7) at the inspection site is achieved according to a machine learning algorithm using a plurality of training or reference image signals. Reference or training image signals can be obtained from calibrated reference masks or wafers or from a model-based simulation. Thereby, it is possible to identify image modes with high significance to determine an edge position, a feature with, a micro-defect, an edge-slope or an edge roughness with high accuracy.

After precisely determining a topography and a material composition of a layer edge, a feature size or a micro defect with high resolution below 2 nm, preferable below 1 nm, even more preferably below 0.5 nm, an electron beam assisted repair or editing process can be triggered, initiated or terminated.

Other advantages of the embodiments of the present disclosure will become apparent from the following description in conjunction with the accompanying drawings. The invention is not limited to the embodiments and examples, but is also comprising variations, combinations, or modifications thereof. Other embodiments of the invention will be apparent to those skilled in the art from consideration of the specification and practice of the invention disclosed herein. For example, the apparatus and the usage of the method defined in this application is not limited to the usage of an electron beam as charged particle. Rather, any particle beam can be used which is capable to induce a local chemical reaction of a precursor gas at the position at which the particle beam hits a surface of a sample and where a corresponding gas is provided. Examples of alternative particle beams are ion beams, metal beams, molecular beams and/or photon beams.

### BRIEF DESCRIPTION OF DRAWINGS

FIG. 1 shows an apparatus for mask repair according to the first embodiment of the invention.

FIG. 2 illustrates the collection of backscattered electrons within the apparatus of FIG. 1.

FIGS. 3A to 3D illustrate the effect of an immersion field F on the angular distribution of backscattered electrons for different landing energies of primary electrons.

FIGS. 4A and 4B illustrate the effect of different immersion fields F1 and F2 on the angular distribution of backscattered electrons.

FIGS. 5A and 5B show the topography effect for backscattered electrons at large immersion fields F.

FIG. 6 illustrates the shadowing effect at the example of an edge of an absorber layer.

FIG. 7 illustrates an example of a corrected electron microscope CSEM according to the invention.

FIG. 8 illustrates an example of the primary beam focusing unit, comprising a shielding grid.

FIG. 9 illustrates the method according to the second embodiment of the invention.

FIGS. 10A to 10C illustrate an example of an imaging mode according to the invention.

FIGS. 11A to 11C illustrate three further examples of different imaging modes according to the invention.

FIGS. 12A to 12C illustrate the selected segments of the angular spectrum of the backscattered electron distribution according to the three examples of different imaging modes of FIGS. 11A to 11C.

FIG. 13 illustrates the detected backscattered electron intensity distributions, obtained by an image scan over a layer edge according to the three further examples of different imaging modes of FIGS. 11A to 11C.

FIGS. 14A to 14C illustrate a detection unit with a plurality of detector segments of a backscattered electron detector.

FIGS. 15A and 15B illustrate the third embodiment of the invention, including the action of a dispersing unit.

FIGS. 16A and 16B illustrate a high precision mask repair operation according to the fourth embodiment of the invention utilizing the apparatus according to the first embodiments and the methods of the second or third embodiment.

### DETAILED DESCRIPTION

Reference will now be made in detail to exemplary embodiments, examples of which are illustrated in the accompanying drawings. Throughout the description same numbers in different drawings represent the same or similar elements unless otherwise represented.

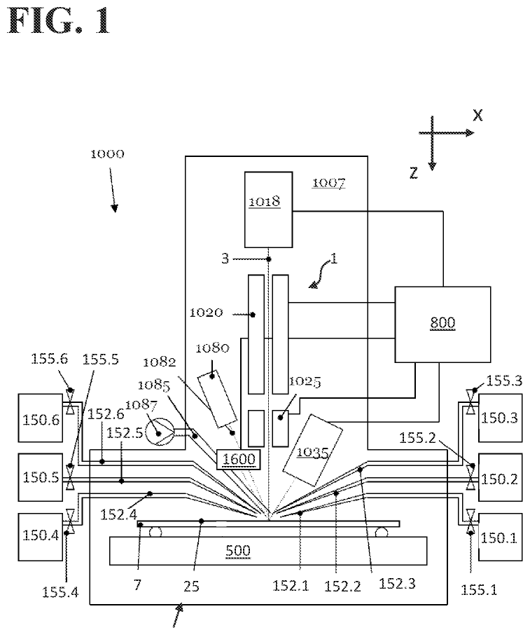

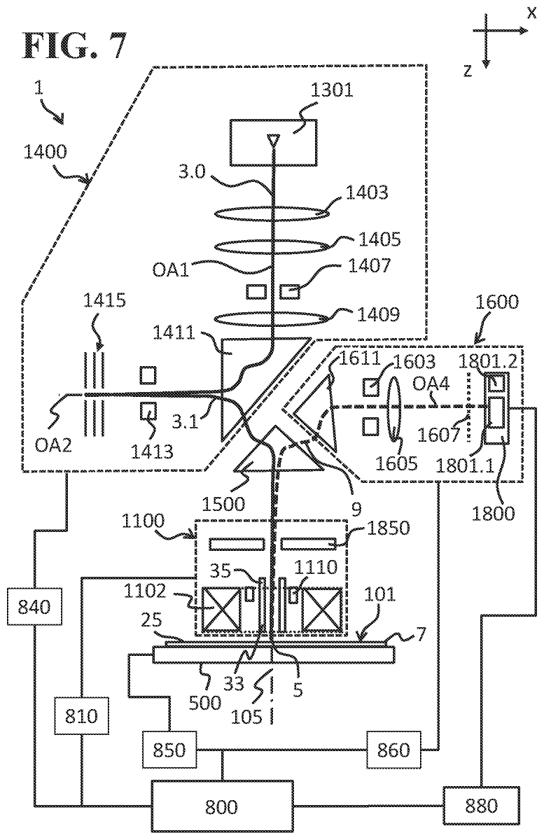

FIG. 1 shows an example of the first embodiment of the invention. FIG. 1 illustrates a cross section of an apparatus 1000 for mask repair, which can be used for repairing local defects of an absorber structure of a mask, and which can at the same time prevent a substrate of the mask from damages during a repairing process. More details of an apparatus and a method of mask repair are described in US 2014/0255,831 A1, which is incorporated herein by reference. The exemplary apparatus 1000 of FIG. 1 comprises a corrected scanning electron microscope 1. The corrected scanning electron microscope 1 comprises an electron source unit 1018 for generation of a primary electron beam 3. Beam imaging, beam correcting and beam deflecting elements 1020 and 1025 direct the primary electron beam 3 and form a focus of the primary electron beam 3 in an image plane (not shown) of the corrected electron microscope or CSEM 1. More details of the CSEM 1 according to the first embodiment are explained in FIG. 7 below.

A mask 7 is arranged on the sample stage 500. The sample stage 500 comprises actuators and is connected to a control unit by which the mask 7 can be placed such that the first surface 25 of the mask 7 is arranged in the image plane of the corrected electron microscope 1. The sample stage 500 can further include one or several control elements to control the temperature of the mask 7.

The exemplary apparatus 1000 uses a primary electron beam 3 as a particle beam. The electron beam 3 can be focused on a small spot with a diameter of less than 10 nanometers, for example less than 5 nm or even less than 3 nm on the surface 25 of the mask 7. The energy of the electrons impinging on the surface 25 of the mask 7 can be varied across an energy range (from a few eV up to 10 keV). When impinging on the surface 25 of the mask 7, the electrons do not cause significant damages of the mask surface 25 due to their small electron mass.

The electron beam 3 is used for scanning across the surface 25 for recording an image of the surface 25 of the mask 7. A detection unit 1600 provides a signal for backscattered and/or secondary electrons which are generated by the interaction of the primary electron beam 3 with the material at the surface 25 of the mask 7. The signal is proportional to the composition and the topography of the material. Typically, masks are fabricated from silicon oxide, with an absorber layer formed by chromium or silicon nitride. EUV masks are typically formed by multilayers formed of molybdenum and silicon (MoSi-Multilayer), with a top layer formed by ruthenium. Absorbers can be formed for example by silicon nitride or tantalum boron nitride. By scanning the primary electron beam across the surface 25 of the mask 7, an image of the mask surface 25 can be obtained and defects of the absorber structure elements of the mask 7 can be determined. Alternatively, defects of the absorber structure of a mask 7 can be determined by exposing a wafer and/or by recording of one or several aerial images of the mask 7 for example determined by use of an AIMS™.

A control unit 800 controls the apparatus 1000 and comprises an image forming unit (not shown) which is configured for obtaining and storing an image of the surface 25 of the mask 7, which is obtained by a scanning operation of the primary electron beam 3. The image forming unit can be configured to execute algorithms realized in hardware and/or software which allow determining and modifying the image of the surface 25 of the mask 7 from the data signal of the detection unit 1600 and can store the calculated or modified image. The control unit 800 comprises a control unit for primary beam forming unit which is configured to control the primary beam formation and the beam forming and beam imaging elements 1020 and 1025. Moreover, the control unit 800 comprises a stage control unit (not shown) configured to control the movement of the sample stage 500.

The apparatus for mask repair 1000 further comprises a plurality of components to manipulate or treat the mask surface 25, for example a laser system 1080 providing a laser beam 1082, an ion beam gun 1035, and a plurality of gas nozzles 152.1 to 152.6 for providing process gases. The primary electron beam 3 is used for initializing the etching or deposition reaction. The accelerating voltage of the electrons is in a range of 0.01 keV to 10 keV. The current of the primary electron beam varies in an interval between 1 pA and 1 nA. The laser system 1080 provides an additional and/or alternative energy transfer mechanism by the laser beam 1082. The energy transfer mechanism can for example selectively activate a precursor gas or can selectively activate components or fragments generated by the decomposition of the precursor gas to efficiently support local repairing processes of for example the absorber structure elements of a mask 7. The exemplary apparatus 1000 comprises a plurality of storage containers 150.1 to 150.6 for different process or precursor gases for processing one or several defects of the absorber structure arranged on the surface 25 of the mask 7. A first storage container 150.1 stores for example a first precursor gas or a deposition gas which is used in combination with the electron beam 3 for generating a protection layer around the defect of an absorber element. A second storage container 150.2 includes, e.g., a chlorine containing etching gas by which the protection layer can be removed from the surface 25 of the mask 7. A third storage container 150.3 stores an etching gas, for example xenon difluoride (XeF2) which is used for locally removing excessive absorber materials, such as chrome or tantalum. A fourth storage container 150.4 stores, e.g., a precursor gas for locally depositing missing absorber material on the surface 25 of the mask 7. A fifth storage container 150.5 and a sixth storage container 150.6 contain two further different gases which can be mixed to the etching gas stored in the third storage container 150.3 as needed. Moreover, the apparatus 1000 may allow installing further storage containers and gas supplies as needed for selective etching or deposition for the repair of mask defect. Each storage container 150.1 to 150.6 is connected to one of the gas nozzles 152.1 to 152.6 via a control valve 155.1 to 155.6. The control valves 155.1 to 155.6 are connected to the control unit 800 for automated gas supply during a mask repair operation. Thereby, the amount of gas particles provided per time unit or the gas flow rate at the place where the electron beam 3 impinges onto the substrate 1010 of the mask 7 is controlled. The distance between the point of impact of the electron beam 3 on the mask 7 and the nozzles 152.1 to 152.3 of the gas supplies is in the range of some millimeters. However, the apparatus 1000 of FIG. 1 also allows the arrangement of gas supplies whose distances to the point of impact of the primary electron beam 3 is smaller than one millimeter.

The apparatus 1000 for mask repair further has a pumping system configured to generate and to maintain the required vacuum inside a vacuum chamber 999. Prior to starting a processing procedure, the pressure in the vacuum chamber 999 is typically in the range of 10⁻⁵ Pa to 2·10⁻⁴ Pa. At the reaction site, the local pressure can typically increase up to a range of approximately 10 Pa. A suction device 1085 in combination with the vacuum pump 1087 enables that the fragments, which are generated by the decomposition of a precursor gas or parts of the precursor gas which are not needed for the local chemical reaction are essentially extracted at the place of the generation from the vacuum chamber 1090 of the apparatus 1000. The suction device 1085 or vacuum pump 1087 may be connected to the control unit 800 to control their operation. A contamination of the vacuum chamber 1090 is avoided since gas components which are not needed are locally extracted from the vacuum chamber 1090 at the position of the incidence of the electron beam 3 and/or the laser beam 1082 before they are distributed and deposited.

The primary electron beam 3 incident on the surface 25 of the mask 7 can charge the substrate surface 25. The charge build up can either be positive or negative. To reduce the effect of the charge accumulation by the electron beam 3, for example a charged particle beam gun such as an ion gun 1035 can be used for irradiating the surface 25 with ions having low energy. For example, an argon ion beam having kinetic energy of some hundreds of volts can be used for neutralizing the surface 25. The control unit can also be configured to control the ion beam source 1035. A positive charge distribution can accumulate on the surface 25 if a focused ion beam is used instead of an electron beam 3. In this case, an electron beam can be used for irradiating the surface 25 to reduce the positive charge.

It is also possible to use two or more particle beams in parallel. A laser system 1080 is incorporated in the apparatus 1000 which generates a laser beam 1082. Thus, the apparatus 1000 allows simultaneously applying an electron beam 3 in combination with a photon beam 1082 to the mask 7. Both beams 3 and 1082 can continuously be provided or in the form of pulses. Moreover, the pulses of the two beams 3 and 1082 can simultaneously partially overlap or can intermediary react on the reaction site. The reaction site is the position at which an electron beam 3 induces alone or in combination with the laser beam 1082 a local chemical reaction of a precursor gas.

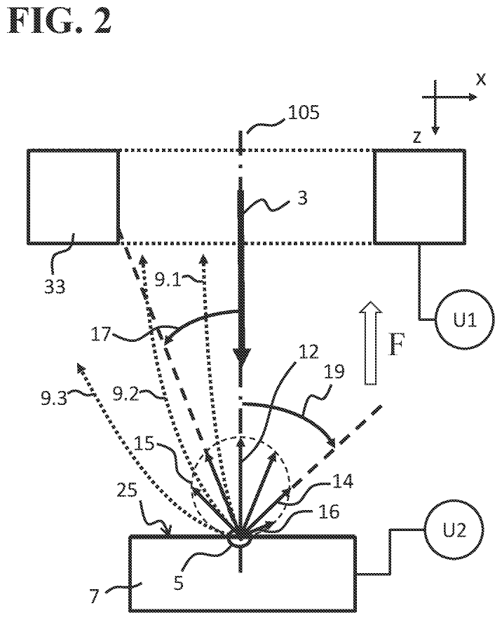

The apparatus 1000 for mask repair is not limited to mask repair, but can also be applied for other applications, such as wafer inspection and circuit editing of fabricated wafers. For semiconductor wafer inspection, circuit editing, mask inspection and mask repair applications, backscattered electrons are used for process control. Backscattered electrons are generated at an intersection area of a primary electron beam with a sample surface with a backscatter coefficient depending on the material at or close to the surface. Typically, backscattering of electrons is described by several interactions with the surface or the material of the sample, including elastic scattering, in-elastic scattering and multiple scattering processes. A simplified backscatter angular distribution is illustrated in FIG. 2. The primary electron beam 3 of the corrected electron microscope 1 propagates along the optical axis 105 of the corrected scanning electron microscope 1 (not shown in FIG. 2) in positive z-direction and focused on an interaction volume 5 close to a surface 25 of the sample 7, for example a wafer or mask. The backscatter angular distribution 15 is approximately simplified by a diffuse scattering process, with a dominating scattering efficiency in backward direction 12, opposite to the incident electron beam 3. All angles of backscattered electrons are illustrated with respect to the optical axis 105 of the electron microscope 1, which is typically aligned perpendicular to the surface 25 of a sample 7. For sake of illustration, effects of electron diffraction at atomic or molecular lattices are hereby neglected. Typically, the primary electron beam 3 is at a voltage of for example 8 keV to 30 keV inside of the corrected electron microscope 1 and is decelerated by an electrostatic potential between the sample 7 and an electrode 33. The electrode 33 can be arranged between the sample 7 and the microscope 1 or can be arranged inside of the magnetic objective lens (not shown in FIG. 2) of the corrected charged particle microscope 1. The electrode 33 can for example be formed by the liner tube reaching into the objective lens of the corrected electron microscope 1. Further electrodes can be provided between electrode 33 and the sample 7 to further influence the electrostatic immersion field above the sample surface 25. An example of an arrangement comprising a further electrode is shown in U.S. Pat. No. 7,910,887, which is incorporated herein by reference.

A first voltage U1 is therefore provided to the electrode 33 and the sample 7 is set at a second voltage U2 for generating a homogeneous decelerating field F between the sample surface 25 and the electrode 33. In an example, the sample is set to ground level with a second voltage U2=0V. Thus, by the potential difference DU=|U1−U2|, an immersion electric field F is formed, which acts as a decelerating field F for the primary beam, such that the primary electrons reach the sample surface 25 at a lower kinetic energy or landing energy LE between 50 eV and 2 kV, but even lower kinetic energies down to LE=0 eV are possible. Typically, there are two different ways to control the LE of the primary electrons. In a first example, the LE is controlled by changing the potential difference between the electrode 33 and the sample 7. In another example, the potential difference DU between the electrode 33 and the sample 7 is kept constant, but the kinetic energy of the primary electron beam upstream of the electrode 33 is changed, for example by a larger extraction potential of the electron source 1018.

The immersion field acts also as a boosting field F for the backscattered electrons. The immersion electric field F has a focusing effect on the angular distribution of the backscattered electrons. Thereby, in this example, the effective collection angle 19 is increased with respect to the acceptance angle 17 of the microscope such that also backscattered electrons, leaving the substrate in direction of up to the arrow 14 and medium angle 19 are still collected. Some examples of backscattered electron trajectories are illustrated, as for example the backscattered electron trajectory 9.1 under small angle, backscattered electron trajectory 9.2 under acceptance angle 19, and backscattered electron trajectory 9.3 with larger starting angle 16, exceeding the effective collection angle 19 of the electron microscope. The collection angle 19 depends thus on the potential difference DU. The larger the potential difference DU, the lower the kinetic energy or landing energy LE of the primary electrons at the surface 25 of the sample, and the larger the collection angle. Typically, at LE about 400 eV, the collection angle 19 is about 0.4 rad (half angle) or NA=0.4 (with NA being the sinus auf the collection angle). At LE=200 eV, the collection angle 19 is about 0.7 rad, or about 400 or NA=0.64. At LE=100 eV, the collection angle increases to 1.3 rad or NA=0.96. At such low energies, the collection angle almost includes electrons scattered at 90°. The angles shown for illustration in FIG. 2 correspond to a LE of about 200 eV.

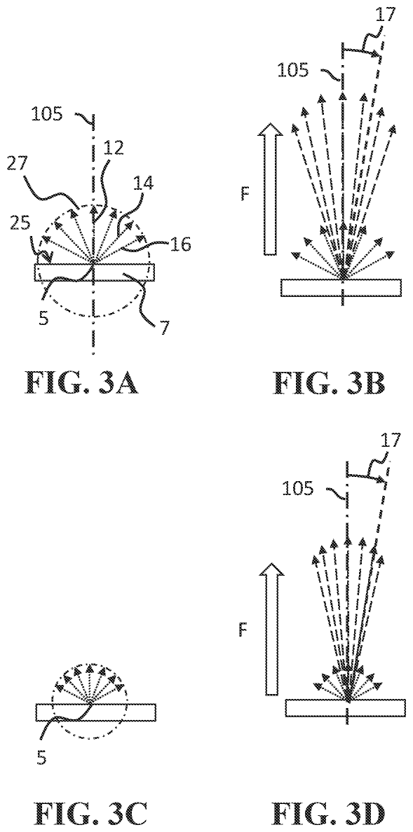

FIG. 3A and FIG. 3B illustrate the focusing effect illustrated in FIG. 2 in a representative illustration of the momentum distribution 27 of the elastically backscattered electrons at a moderate landing energy LE of about 400 eV. At the dwell point 5, a plurality of backscattered electrons is generated with the same energy of the impinging primary electrons, but with different direction or scattering angle. The backscattered electrons comprise backscattered electrons I2 parallel to the optical axis or perpendicular to the surface 25 of sample 7, and backscattered electrons 14 and 16 at moderate and at large angles to the optical axis. FIG. 3B illustrates the effect of the boost or immersion field F to the backscattered electrons. The backscattered electron momentum is increased in direction of the boost field F and some backscattered electrons are collected by the collection angle 17 of the corrected electron microscope 1. FIG. 3C illustrates the momentum distribution 27 of the elastically backscattered electrons at a low landing energy LE of about 200 eV. Again, at the dwell point 5, a plurality of backscattered electrons is generated with the same, now lower energy of the impinging primary electrons with different direction or scattering angle. FIG. 3D illustrates the effect of the boost field F to the backscattered electrons at lower energy. In this example, the lower landing energy of primary electrons is achieved by a lower extraction or acceleration voltage of the electron source 1018. The backscattered electron momentum is even more increased in the direction of the boost field F and more backscattered electrons are collected by the collection angle 17 of the corrected electron microscope 1, in this example even the backscattered electrons at moderate angle 14 are inside the collection angle 17 and are thus collected by the corrected electron microscope 1.

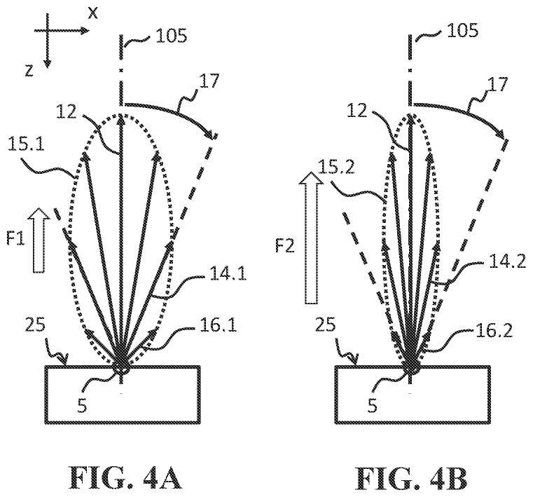

FIG. 4A illustrates the focusing effect with different immersion fields F1 and F2. Like in FIG. 2, the effective backscatter angular intensity distribution 15.1 is illustrated as a result of the acceleration according to a first immersion or boost field F1. The first immersion field F1 corresponds to a first potential difference DU1. The first boosting field F1 acts in z-direction and thus virtually elongates the simplified backscatter angular distribution of FIG. 2 in z-direction, forming an effective backscatter angular intensity distribution 15.1 of ellipsoidal shape. As in FIG. 2, the acceptance angle 17 of the corrected electron microscope 1 (not shown) is illustrated by a dashed line, corresponding to the backscattered electrons under moderate angle 14.1. The acceptance angle 17 corresponds to the collection angle 19 of FIG. 2, by which a backscattered electron under angle 14 is collected. A backscattered electron under the larger angle 16.1 is exceeding the acceptance angle 17 and is therefore not collected.

For even more reduced primary electron landing energies of a corrected electron microscope 1 with a larger second potential difference DU2, the effective in-plane moment of backscattered electrons becomes even smaller. Since the reflected electrons are in this case accelerated by an even larger boost potential DU2, this results in an effective elongation of the reflected electron phase space or effective backscatter angular distribution. FIG. 4B illustrates an example of the effective backscatter angular distribution for even lower primary electron energies, as required for high resolution imaging of the invention. For even lower primary electron energies an even larger potential difference DU2 is applied, leading to an even lower kinetic energy of the primary electrons at the interaction area 5. The backscattered electrons are accelerated in the direction of the z-axis by the larger second boosting field F2, generated by the larger potential difference DU2, and experience an even larger focusing effect. Therefore, the width of the effective backscatter angular distribution 15.2 has an even more ellipsoidal shape with a larger ellipticity, given by the ratio of the long axis along the z-direction to the short axis in x direction. Consequently, the backscattered electron under angle 14 is well within the effective collection angle 17, as illustrated by backscattered electron direction 14.2. In this example, even the backscattered electron scattered under large angle 16 is collected, as illustrated by arrow 16.2. Thus, even electrons which are backscattered at angles almost parallel to the surface 25 are collected. A similar result is obtained in the case of equal boost fields F=F1=F2 and a reduction of the landing energy of the primary electrons for example with a lower extraction potential at the electron source 1018.

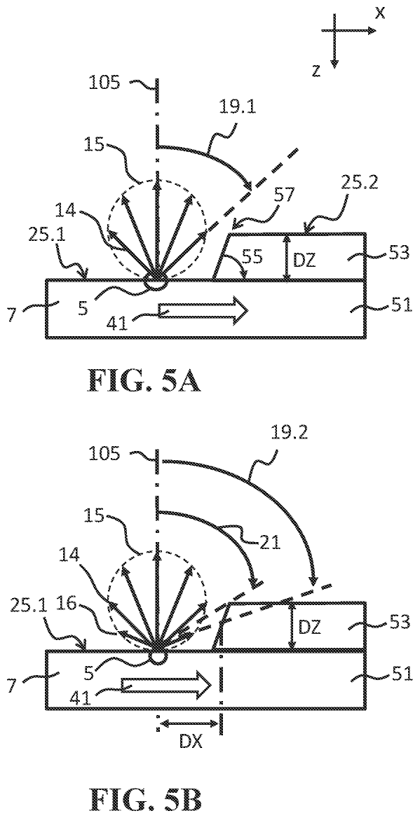

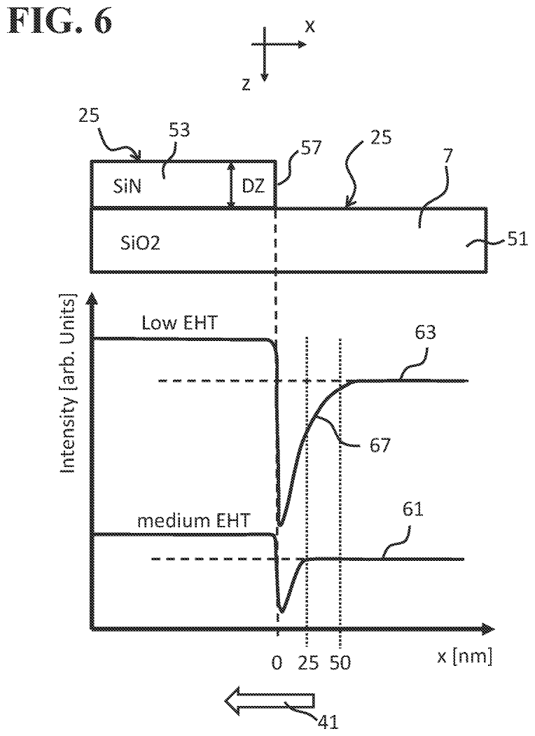

The larger effective collection angle 19 (see FIG. 2) for low energy electrons has on the one hand the advantageous effect that more backscattered electrons are collected and a larger signal to noise ratio is obtained, even for high resolution imaging with low energy electrons. The larger effective collection angle 19, however, increases the impact of topography effects of a typical semiconductor sample, such as a wafer or a mask. FIGS. 5A and 5B illustrate the effect of a layer edge of a semiconductor mask during inspection. FIG. 5A illustrates the condition with a medium potential difference DU1, which a moderate kinetic energy LE1 of primary electrons of about 300 eV to 400 eV. A primary electron beam is scanned across the surface 25 along scanning direction 41. At an interaction position or dwell point 5.1, backscattered electrons are generated. All backscattered electrons in the effective collection angle 19.1 are collected and contribute to the image signal. Close to the surface segment 25.1 of the substrate or lower layer 51, a layer edge 57 of an absorber layer 53 is placed. The absorber layer 53 has a first thickness DZ of about 15 nm to 100 nm, for example 70 nm, and is for example formed by silicon nitride. The absorber layer 53 forms an edge 57 with a slope angle 55 of between 78° and 90° with the surface segment 25.1 of the first layer 51. The same situation is illustrated in FIG. 5B with a lower kinetic energy LE2<<LE1 of the primary electrons when reaching the interaction volume 5. Typical landing energies of corrected electron microscopes are below 500 eV, for example in the range between 100 eV and 200 eV or even below 100 eV. In the regime below 150 eV, resolutions of about 1 nm or even below 1 nm are possible, as required for mask repair or circuit edit applications. In this example, the effective collection angle 19.2 is increased as described in FIG. 2 to 4, such that also backscattered electrons under very large angles, for example as illustrated by arrow 16, are collected. Some of these backscattered electrons are obscured by the layer 53, where the backscattered electrons are either absorbed or scattered again. This geometrical effect leads to a reduced backscatter electron signal, while the signal gets smaller with smaller distance between the dwell point 5 and the edge 57. For illustration, a geometrical shadowing angle 21 is illustrated, until which backscattered electrons can reach the electron microscope and the detector unit. For these low energy backscattered electrons, the backscattered electron signal depends on the distance DX between dwell point 5, layer thickness DZ and slope angle 55 (see FIG. 5A). Currently, the layer thickness DZ of an absorber layer in a semiconductor mask is about 60 nm to 70 nm, but a further reduction to below 50 nm is possible. The backscattered electron signal may also be influenced by scattering of the backscattered electrons at the layer edge 57 and by any charging effects, which can be build up in layer 53 or substrate 51 by backscattered electrons. FIG. 6 illustrates the result of a layer edge in the backscattered electron signal. Close to the layer edge 57, electrons emitted under a large polar angle in the direction of the edge 57 are lost due to the shadowing or topography effect and do not reach the detector. For medium LE, only few backscattered electrons are collected with the smaller effective collection aperture 19.1, leading to a lower backscattered electron signal 61 with a larger relative noise level and a lower signal-to-noise ratio (SNR). At low LE below 400 eV, the effective collection aperture 19.2 is significantly increased and a larger number of backscattered electrons is collected, leading to a larger backscattered electron signal 63 with higher SNR. Due to the larger collection angle 19.2, also the impact of shadowing increases, leading to a larger reduction of backscatter electron yield even at a larger distance to the layer edge, for example of distances of up to 50 nm or even more. Both signals 61 and 63 show a difference in the backscattered electron yield with respect to the two materials of the test sample (silicon dioxide versus silicon nitride), but especially the low LE signal 63 is entangled with a strong disturbance of the signal from the shadowing or topographic effect from the layer edge 57. In conventional microscopes with conventional imaging techniques, the increased topography signal 67 can reach an extension of about 50 nm, such that for example mask structures with a distance below 50 nm cannot be detected any more with the required precision of a mask repair operation.

According to the invention, the increased topography signal 67 at low LE imaging is utilized to extract information about the edge, including the edge position within nm-accuracy and the edge slope, for example the slope angle 55. The slope angle of attenuated phase shift mask for EUV masks can for example be between 81° and 86°. According to a further aspect of the invention, a process control of a mask repair is improved by considering the topography effects.

FIG. 7 illustrates further details of the corrected electron microscope (CSEM) 1 according to the first embodiment of the invention. The CSEM 1 is suitable for low energy backscattered electron imaging with the high resolution and the high accuracy as required for mask repair and circuit edit applications described above. The corrected electron microscope 1 comprises a corrected beam forming unit 1400, a beam divider unit 1500, a primary beam focusing unit 1100 and a detection unit 1600.

The corrected beam forming unit 1400 comprises an electron beam generator 1301 for generating a beam of primary electrons 3. The primary electron beam 3 is guided along a beam path, which corresponds to the first optical axis OA1. For collimating, condensing, and imaging the primary electron beam 3, a first electrostatic lens 1403, a second electrostatic lens 1405, and a third electrostatic lens 1409 are used. The condenser optical unit made up from lenses 1403 and 1405 may also comprise further condenser lenses for adjustment of the electron beam current collected from the electron source 1301. For adjustment and control, a first electrostatic or magnetic beam deflection unit 1407 is arranged within the primary beam path. The first deflection unit 1407 can be established as a quadrupole or octupole unit and can be configured for lateral adjustment, beam direction adjustment and/or adjustment of an astigmatic shape of the primary electron beam 3.0. The first deflection unit 1407 can comprise a first multi-pole unit and a second, subsequent multi-pole unit. With the first multi-pole unit and the second multi-pole unit, the primary electron beam 3 can be adjusted relative to the axis of the third electrostatic lens 1409 and the entrance window of the second beam deflection unit 1411. With the second deflection unit 1411, the primary electron beam is deflected in direction of a second optical axis OA2, which is at an angle between 30° to 120° to the first optical axis OA1. More details of the second beam deflection unit 1411 are described in U.S. Pat. No. 6,855,939 BB, which is hereby incorporated by reference.

The primary electron beam 3.0 is then guided along the second optical axis OA2 to an electrostatic mirror 1415 via a third deflection unit 1413. At the electrostatic mirror 1415, the primary electron beam 3 is reflected and chromatic aberrations, spherical aberrations and field curvature are at least partially corrected and a corrected primary electron beam 3.1 is formed. On its path to or from the electrostatic mirror 1415, the primary electrons 3 may further pass at least one electrostatic lens (not shown). The corrected primary electron beam 3.1 propagates along the second optical axis OA2 and re-enters the beam deflection device 1411. In a magnetic sector of the first beam deflection device 1411, the reflected primary beam 3.1 is separated from the incident primary beam 3.0 and guided to a beam divider unit 1500. Beam divider unit 1500 comprises at least one magnetic sector for deflecting the corrected primary electron beam 3.1 to the third optical axis 105. The beam divider unit 1500 may comprise further magnetic sectors or electrostatic elements. The electrons of the corrected particle beam 3.1 from the beam divider unit 1500 propagate along the third optical axis 105 and enter the primary beam focusing unit 1100. The primary beam focusing unit 1100 focuses the corrected primary beam 3.1 on the surface 25 of a sample 7 which is intended to be examined. Within the primary beam focusing unit 1100, the corrected primary electron beam 3.1 is deflected by scanning deflector 1110 and focused by objective lens 1102 to form a corrected electron focus point with low diameter and for high imaging resolution on the surface 25 of the sample 7. The objective lens 1102 may be implemented as a combination of a magnetic lens and an electrostatic lens. The correction of the chromatic and spherical aberrations of the objective lens 1102 by the electrostatic mirror 1415 allows lower acceleration voltages of the primary electrons and thus lower landing energies LE of the primary electrons. To achieve the low landing energies LE required for the high resolution, the primary electrons of the electron beam 3.1 are decelerated by the immersion field F (see FIG. 2). Above the sample stage 500, an electrode 33 is arranged for generating the immersion field F. In the example, the primary beam focusing unit 1100 further comprise a beam guiding or liner tube 35 at a fixed potential, forming a free drift space of the primary electrons 3. The lower or beam exiting end of the beam guiding tube forms the electrode 33. After leaving the beam guiding tube 35, electrons of the corrected electron beam 3.1 are decelerated by the immersion field to the potential of the sample 7. The sample 7, such as a wafer or a mask, is arranged via a sample holder (not shown) on a movable sample stage 500. Via the sample holder, a potential U2 is provided to the sample 7, for example by stage control unit 850. The potential U2 may be the ground potential with U2=0V or a higher potential. The sample stage 500 may comprise for example six actuators for positioning the sample surface 25 with six degrees of freedom with respect to an image plane 101 of the corrected electron microscope 1.

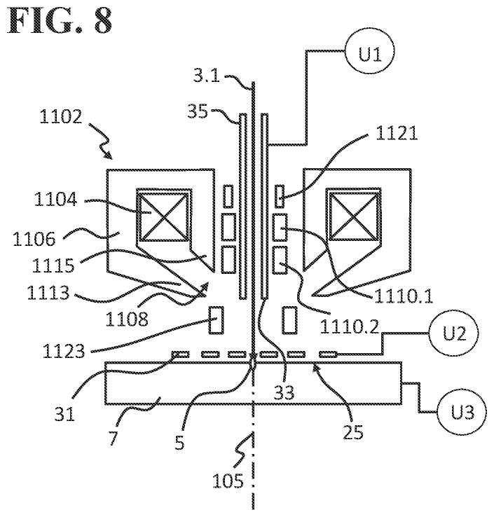

The immersion field F is sensitive to charging effects on the surface 25 of the sample 7. In an example of the embodiment, a shielding electrode is attached to the primary beam focusing unit 1100. With the shielding electrode, an electrostatic field by charging effects of the sample surface 25 are shielded and the immersion field is not influenced. FIG. 8 illustrates the arrangement of a shielding electrode 31 at an example. The shielding electrode 31 is formed by a grid formed of an electrically conduction material and connected to the second voltage U2. The electrode material can for example be copper, silver, or a grid coated by copper, silver, nickel silver or gold. The grid electrode is approximately 10 μm thick and has at least an opening or aperture of about 30 μm in diameter.

In an example, the second voltage U2 applied to the grid electrode 31 can be equivalent to ground level of 0V, but also other voltages are possible. The lower end of the beam liner tube 35 forms the opposing electrode 33, to which a first voltage U1 is applied. The first voltage U1 can be between 1 kV to 10 kV. The corrected primary electron beam 3.1 enters the beam liner tube 35 with a slightly higher kinetic energy EHT of for example EHT=U1+dU and drifts through the liner tube 35. After deceleration in the immersion field between the electrode 33 and the grid electrode 31, the primary electrons 3.1 have a kinetic energy of dU. The energy difference dU can be between 500 eV and 50 eV or even less. The primary electron beam 3.1 passes the grid electrode 31 at the at least one aperture. The grid electrode 31 is spaced with respect to the sample surface by a small distance of less than 20 μm, preferably below 15 μm. The electrons, which are decelerated by the immersion field between grid electrode 31 and opposing electrode 33 are focused on the sample surface 25 by the objective lens 1102, which is formed as a so-called axial gap lens. The objective lens 1102 is formed as a magnetic lens with at least a first coil 1104 and a yoke 1106. The upper pole shoe 1115 and the lower pole shoe 1113 of the yoke 1106 form an axial gap 1108, thereby a magnetic immersion field is minimized. However, other objective lenses with for example a radial gap are possible as well. The primary electron focus point 5 is formed on the surface of the lens and raster scanned with the scanning deflectors 1110.1 and 1110.2. The sample 7 is in this example connected to a third potential of a third voltage U3, which can be equal or less compared to the second voltage U2 (U3≤U2). Thereby, a low landing energy of below dU is achieved. In an example, both second and third voltages U2 and U3 are set equal and both the grid electrode 31 and the sample 7 are connected to ground level. The landing energy LE of the primary electrons is then equal to the difference dU of the kinetic energy of the acceleration voltage of the primary electrons 3.1 to the liner tube potential UL. In a third example, the third voltage or potential U3 is larger the U2. Thereby the collection angle 19 can be adjusted precisely. In this example, the third voltage or potential U3 is preferably between U1 and U2 with U1>U3>U2.

The scanning deflectors 1110 of this example are magnetic deflectors and serve to first deflect the primary beamlet 3.1 over the surface 25 of the sample and second to adjust an angle of the primary beamlet 3.1 with respect to the optical axis 105 of the primary beam focusing unit 1100, which should be arranged normal to the surface 25. The primary beam focusing unit 1100 of FIG. 8 further comprises a first electrostatic multipole corrector 1123 arranged between the grid electrode and the liner tube 35. Thereby, the immersion field can be influenced, and a beam aberration can be minimized during a scanning operation with the scanning deflectors 1110.1 and 1110.2. The first electrostatic multi-pole corrector 1123 can further be used to scan the primary electron beam 3 over the surface 25 of the sample 7, for example in a fast-scanning mode with the electrostatic poles of the first electrostatic multi-pole corrector 1123 during a repair operation. The first electrostatic multipole corrector 1123 can for example be an octupole corrector or a corrector with twelve poles, configured to correct an astigmatism or a trefoil aberration of the primary beamlet. A second, magnetic multipole corrector 1121 can be arranged inside the objective lens 1102 and around the liner tube 35. With such an arrangement of the primary beam focusing unit 1100, very low landing energies with a very high resolution are possible. With the arrangement, a collection of a large angular spectrum of backscattered electrons is possible, and a mask inspection or repair application with the specification requirements discussed above is possible.

The description of the corrected electron microscope 1 according to the first embodiment is now continued at the illustration of FIG. 7. The corrected electron beam 3.1 which is focused onto the sample 7 into an interaction volume 5 or dwell point 5 and interacts with there the sample 7 and secondary and backscattered electrons 9 are generated, as describe above in FIGS. 2 and 3. The secondary electrons or the backscattered electrons are accelerated again by the immersion field, as described above. The backscattered electrons are imaged by the objective lens 1102 to form an intermediate image of the dwell point 5. At the intermediate image position (not shown), an aperture 1850 can be positioned with an in-lens detector for detecting secondary electrons. The backscattered electrons 9 pass the aperture 1850 in the in-lens detector and enter the beam divider unit 1500. In the beam divider unit 1500, the backscattered electrons propagate in opposite direction to the corrected primary electron beam 3.1 and are thus deflected along a different beam path. The backscattered electron beam 9 enters then the detection unit 1600. The detection unit 1600 comprises a fourth deflection unit or dispersion unit 1611, a fifth deflection unit 1603 for displacing the backscattered electron beam 9, an image forming lens 1605 and a grid electrode acting as an electron energy filter 1607. The detection unit 1600 further comprises an electron detector with at least a first detector segment 1801 and preferably at least a second backscattered electron detector segment 1802. The detection unit 1600 can comprise a sixth deflection unit downstream of the lens 1605 (not shown), by which an angle of the displaced backscattered electron beam 9 can be controlled.

After passing the fourth deflection unit or dispersion unit 1611, the backscattered electron beam travels with its center of gravity along the fourth optical axis OA4. The fourth deflection unit or dispersion unit 1611 may operate as a Wien deflector, which can control a deflection angles or the backscattered electrons according to the kinetic energy. The kinetic energy of backscattered electrons may deviate from the kinetic energy of the primary electrons due to inelastic scattering processes and due to the focusing power of the immersion field F. The immersion field F dispersion accelerates any backscattered electron in the same direction of the optical axis 105 and thus may increase the kinetic energy of a backscattered electrons at high scattering angles. With the fourth deflection unit or dispersion unit 1611, a predetermined amount of dispersion correction or dispersion compensation can be achieved and an efficient filtering of backscattered electrons with respect to their kinetic energy is enabled. The fifth deflection unit 1603 can comprise a first multi-pole unit and a second, subsequent multi-pole unit for deflecting the backscattered electron beam 9. Thereby, a specific energy spectrum or a specific angular spectrum of the backscattered electrons can be deflected in direction of the backscattered electron detector 1800. The backscattered electron detector 1800 comprises in this example a first electron detector segment 1801.1 and a second electron detector segment 1801.2. The electron lens 1605 can be a magnetic lens or an electrostatic lens. With the lens 1605, the backscattered electron beam 9 can be defocused or focused on the detector elements for an even more detailed selection of an angular and energy spectrum of the backscattered electron beam 9. The energy filter 1607 can be for example a wire mesh at a specific repelling potential for blocking low energy backscattered electrons. Such an energy filter serves as a high-pass energy filter, which blocks backscattered electrons below a threshold energy. Thereby, an even more specific energy filtering can be achieved. The detection unit 1600 may comprise further elements, such as an anti-scan deflection unit for compensating a residual scanning error of the backscattered electron beam 9. The backscattered electron beam 9 passes the same scanning deflector 1110 as the corrected primary beam but may suffer from a slight residual scanning error of the scanning operation of the scanning deflector 1110 compared to the primary beamlets due to the different beam paths of the backscattered electrons, traversing the scanning deflector 1110 at slightly different energies or angles compared to the corrected primary electron beam 3.1.

It should be appreciated, however, that the corrected electron microscope 1 is not restricted to deflection angles of 90 degrees. Rather, any suitable deflection angle can be selected by the beam deflection units 1411, 1500 and 1611, for example between 30 degrees and 90 degrees or even 110 degrees, so that the first optical axis OA1 does not need to be parallel to the third optical axis 105 and the second optical axis OA2 does not need to be parallel to the fourth optical axis OA4. This example of a CSEM 1 comprises a mirror corrector for correcting e.g., chromatic and/or spherical aberration. A corrected electron microscope 1 is however not restricted to an SEM with a mirror corrector. Rather, the particle beam device having other types of correction units, for example series of octupole correctors and/or Wien filters, are possible as well. The energy filter 1607 is not limited to repelling fields but may comprise also a Wien filter or other energy filters as well.

The corrected beam forming unit 1400 is connected to the beam forming control unit 840, which is a component of the control unit 800. A further component of the control unit 800 is the stage controller 850, by which alignment and movement of the stage 500 is controlled and by which the sample potential U2 can be provided and controlled. Control unit 800 is further connected to the primary electron beam focusing unit 1100 via the scanning and focusing control unit 810. A further component of the control unit 800 is the detection control unit 860, by which the operation of the dispersion unit 1611, the fifth deflection unit 1603, the focusing lens 1605 and the energy filter 1607 is controlled. The image acquisition unit 880 is connected to the backscattered electron detector 1800 for acquisition of the backscattered electron signals and converting the signals into digital image data.

The detection control unit 860 is configured to control the dispersion unit 1611, the fifth deflection unit 1603, the focusing lens 1605 and the energy filter 1607 in a first mode of operation and at least in a second mode of operation. In the first mode of operation, a predetermined first angular spectrum segment of the backscattered electrons with a first energy spectrum is collected and in a second mode of operation, a predetermined second angular spectrum segment of the backscattered electrons with a second energy spectrum is collected, wherein at least either the first and the second angular spectra or the first and second energy spectra or both are different. The control unit 800 is further configured to selectively switch between the at least two operation modes of the detection unit 1600. Thereby, a topography information can be extracted from the angular distribution or energy distribution of the backscattered electrons. In an example, the control unit 800 is configured to analyze the image data obtained by the at least two operating modes and extract a topography information from the analysis. In an example, the control unit 800 is configured to analyze the image data separately obtained by first and second detector segments 1801.1 and 1801.2 and extract a topography information from the analysis. In an example, the detector 1800 comprises more detector segments, for example four detector segments, seven or nine detector segments, or even more detector segments for a more detailed analysis of the angular and energy spectrum of the backscattered electron beam 9. More details of the operation of the corrected electron microscope 1 and the apparatus for mask repair 1000 according to the first embodiment of the invention will be described at the second embodiment of the invention.

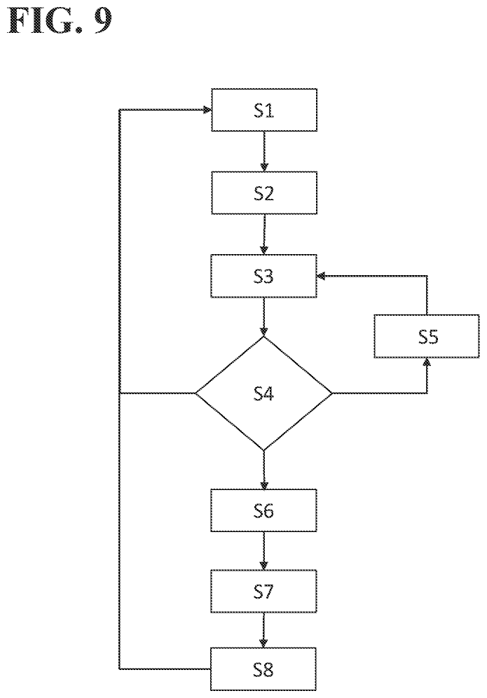

With an apparatus according to the first embodiment, full access to the backscattered angular spectrum is possible. With the detection system 1600, it is possible to obtain information about the momentum distribution. Momentum distribution and angular spectrum are similar for backscattered electrons of similar energy. Therefore, different parts of the angular or energy distribution can be used for dynamic image acquisition for high resolution imaging with a corrected, low energy electron microscope 1. This allows to disentangle material contrast from topography information and enhance the resolution and accuracy of a mask inspection or mask repair application. According to the second embodiment of the invention, a method of mask inspection for mask repair is provided. A method according to the second embodiment is illustrated in FIG. 9.

In a Step S1 an inspection site of a mask or a wafer is aligned with the stage 500. A series of inspection sites, for example the positions for mask repair processes are determined for example by an aerial image generation of the mask or from the analysis of a printed wafer. In the apparatus according to the invention, the coordinate system of the mask or wafer is then registered, and the mask is aligned within the image plane 101 and a first inspection site is aligned at the optical axis 105 of the apparatus 1000 (see FIGS. 1 and 6 for reference). Several known methods for registration and alignment can be applied.

In step S2, at least two imaging modes for high resolution imaging of the inspection site are selected. The at least two inspection modes are selected for detection and extraction of topography effects, and for separation of topography effects from material contrast effects. For each inspection mode, a set of parameters of at least one adjustment element of the detection unit 1600, including the parameters for at least one of the dispersion element 1611, the deflection unit 1603, the lens 1605 and the energy filter 1607 are selected. Each of the imaging modes for high resolution imaging operate with low kinetic energy electrons with LE<500 eV, for example LE below 400 eV, or even below 200 eV, for example 150 eV. Each imaging modes for high resolution imaging can operate at the same LE, or at different LEs, for example a first LE1=200 eV and a second LE2=150 eV.

In step S3, a first image of the inspection site is obtained in a default imaging mode. The default imaging mode can be the first imaging mode for high resolution imaging according to the selection of step S2 or any other imaging mode.

In step S4, the image obtained from step S3 and it is determined, whether a subsequent image is required with a subsequent imaging mode. The determination can comprise at least one of the following components:
4a) it is determined whether the image comprises the expected feature of the inspection site and whether the expected feature to be measured has the expected orientation. If there is an error in the alignment of the inspection site, the method starts again with step S1.
4b) it is determined whether the first and at least second image according to the list of the at least two different imaging modes is obtained or whether images according to some inspection modes are missing. If further images according to an inspection mode are missing, the method continues with step S5. If all images according to the at least two imaging modes according to the selection of step S2 are obtained, the method continues with step S6.

In step S5, a next inspection mode of the list of at least two imaging modes according to step S2 is selected and the parameters of the corrected electron microscope 1 are adjusted accordingly. The imaging mode of the CSEM 1 is changed and a second, high resolution imaging mode of the CSEM 1 with low-energy electrons is installed. The change of the imaging mode from the first high-resolution imaging mode to a second or further high-resolution imaging mode comprises the change of parameters for the detection unit 1600, including the parameters for at least one of the dispersion element 1611, the deflection unit 1603, the lens 1605 and the energy filter 1607. Each of the imaging modes for high resolution imaging operate with low kinetic energy electrons with LE<500 eV, for example LE below 400 eV, or even below 200 eV, for example 150 eV. Each imaging modes for high resolution imaging can operate at the same LE, or at different LEs, for example a first LE1=200 eV and a second LE2=150 eV.

An image acquisition according to step S3 is repeated, and a subsequent image is obtained. Steps S3 to S5 are repeated until all images according to the at least two imaging modes are obtained, and a set of images is obtained. When all images of the set of images according to the selection of step S2 are obtained, the method continues with step S6.

In step S6, the set of images is analyzed and at least one of the following measurements results is extracted:
a) a topography information is extracted or separated from a material contrast;
b) an edge position of a layer edge is determined with an accuracy below 2 nm, preferable below 1 nm, even more preferably below 0.5 nm;
c) a feature dimension is determined with an accuracy below 2 nm, preferable below 1 nm, even more preferably below 0.5 nm;
d) an edge slope is determined;
e) an edge roughness is determined;
f) micro-defects are determined, for example contamination particles.

In step S7, the extracted measurement result is analyzed and a repair process or an editing process is determined and initiated or terminated.

In step S8, it is determined whether
a) an inspection and repair process according to steps S1 to S7 must be repeated at the same inspection site, or whether
b) the method can be continued at a next inspection site, or whether
c) the end of an inspection of a mask or wafer has been reached and the method can be started again with a new mask or wafer.

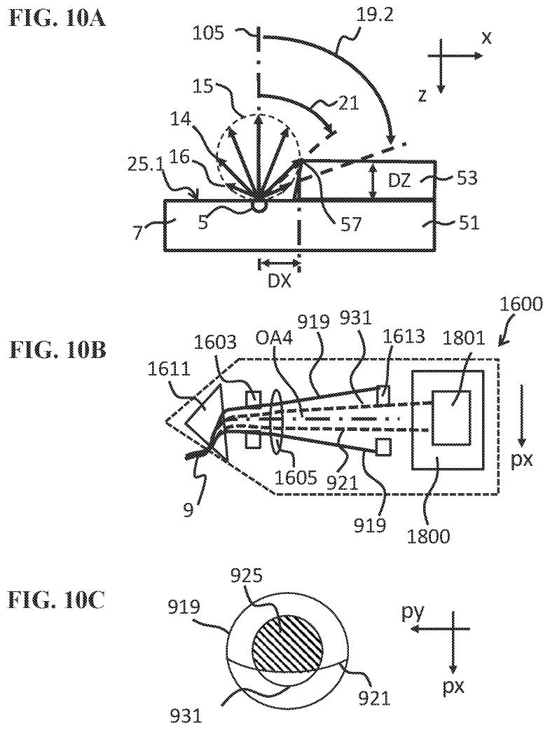

Next, the selection of the imaging modes according to step S2 is described in more detail. An example of an inspection according to the invention is illustrated in FIGS. 10A to 10C. FIG. 10A is like the situation illustrated in FIG. 5B, with a collection angle 19.2 of for example about 70° corresponding to a primary electron energy EHT of about 125 eV. An inspection position or dwell point 5 is at a distance DX to an edge 57 of a layer 53 on a substrate 51. The thickness of the layer 53 is for example 70 nm. As in the simplified illustration of the topographic effect in FIG. 5B, the edge forms a shadowing region, limited by a shadow angle 21. FIG. 10B illustrates a detection unit 1600 in a first imaging mode, which is like a conventional imaging operation of a corrected electron microscope 1. The dispersing element 1611 is set to a standard correction of a dispersion. After the dispersing unit 1611, the backscattered electron beam 9 has a divergency illustrated by boundary lines 919. The divergency corresponds to an angular spectrum or momentum distribution of the backscattered electron beam 9, arranged symmetrically with respect to the fourth optical axis OA4. The deflection system 1603 of the detection unit 1600 is in an off state. The lens 1605 is also in an off stage. In this example, the detection unit 1600 further comprises an aperture stop 1613. A first detector element 1801 of the electron detector 1800 is arrange downstream of the aperture stop 1613, which limits the collected angular spectrum or momentum spectrum with coordinates (px, py) of the backscattered electron beam as indicated by angle 931. At the lower side of the illustration, the collected angular spectrum of backscattered electrons is further limited by the shadow angle 921 of the layer edge 57. In this illustration, the positive momentum direction px is parallel to the z-axis. FIG. 10C illustrates the collected backscattered electron distribution 925 in angular or momentum space with coordinates px and py. The figure shows the maximum collection angle 919 of the corrected electron microscope 1, the shadow angle line 921 and the collection aperture 931 corresponding to the aperture stop 1613. The collected backscattered electron signal corresponds to the integral over the circle 931.

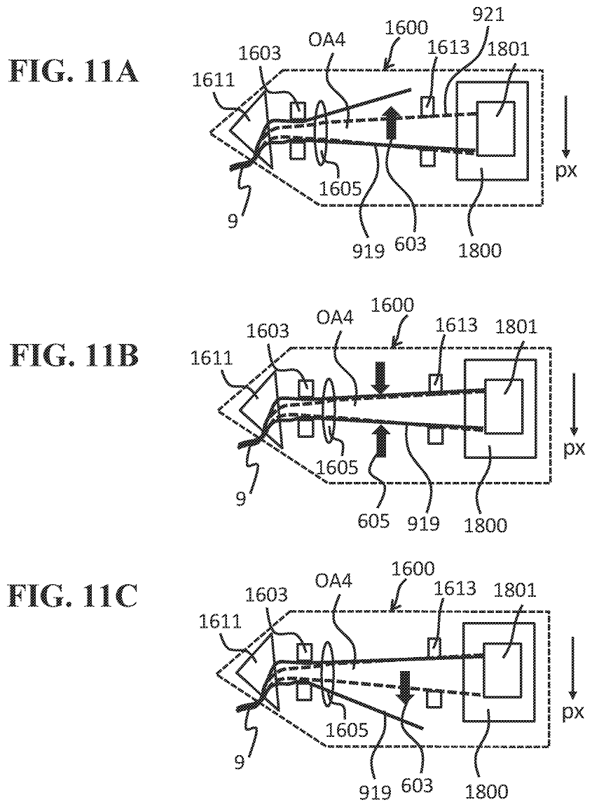

FIGS. 11A to 11C illustrate three examples of imaging modes according to the invention. For reasons of illustration, the acceptance angle limitation 921 according to the aperture 1613 is included in the figures. FIG. 11A illustrates a first imaging mode, wherein the detection unit 1600 is controlled to achieve a first deflection 603 in negative px-direction of the backscattered electron beam 9 by the deflector 1603. Thereby, the topography effect of the layer edge is increased to a maximum. FIG. 11B illustrates a second imaging mode, in which detection unit 1600 is controlled to achieve the effect of a focusing action 605 of the focusing lens 1605. In this example, the focusing power of the lens 1605 is adjusted such that the maximum collection angle 919 of the backscattered electron spectrum corresponds with the acceptance angle of the aperture stop 1613. Thereby the collection efficiency of backscattered electrons from the backscattered electron beam 9 is increased to a maximum.

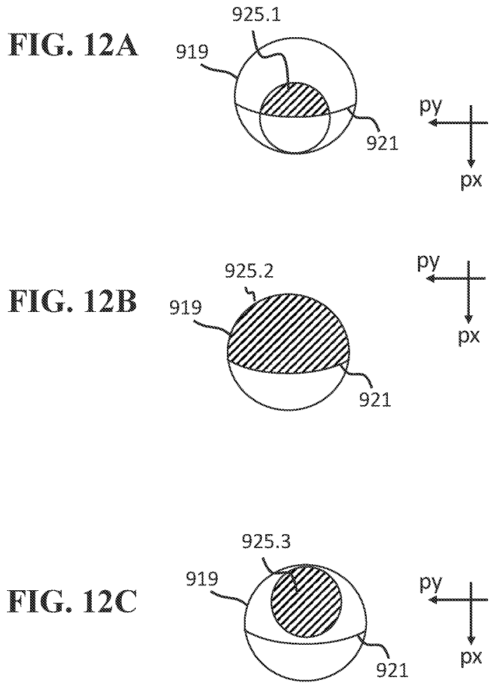

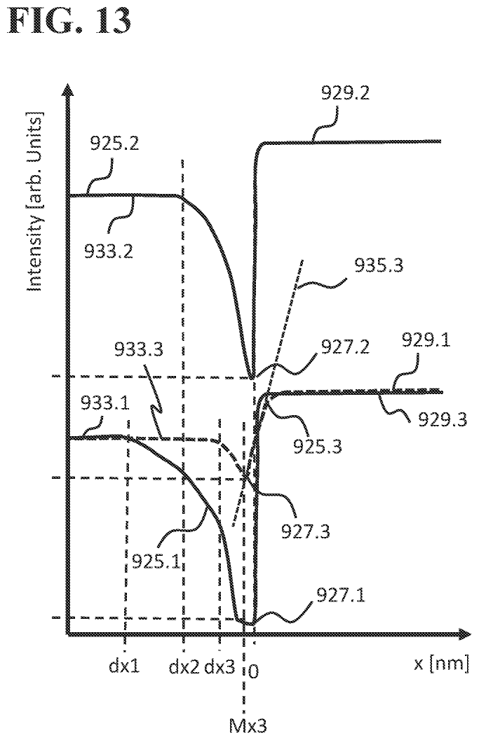

FIG. 11C illustrates a third imaging mode, in which detection unit 1600 is controlled to achieve a second deflection 607 via the deflector 1603 in positive px-direction. Thereby, the topography effect of the layer edge 57 is reduced to a minimum. Corresponding FIGS. 12A to 12C illustrate the effect to the detected angular distribution 925.1 to 925.3 of the three imaging modes at the example of the layer edge 57 according to FIG. 10A. The shadow line 921 is unchanged with respect to the collected backscattered electron distribution 919. As illustrated in FIG. 12A, due to the first deflection 603 in negative px-direction, more of the backscattered electrons, which are scattered in positive x-direction collected and detected, and consequently a larger fraction of the backscattered is lost due to the shadow effect of the layer edge 57. FIG. 12B illustrates the case when the complete backscattered electron spectrum, limited by the collection angle 919, is detected. Here, the signal reaches a maximum. FIG. 12C illustrates the effect of the second deflection 605 in positive px-direction, where the impact of the topography effect of the shadowing effect is reduced to minimum. FIG. 13 compares the three intensity signals of a line scan across the layer edge 57 in x-direction according to the three imaging modes. The first intensity signal 925.1 corresponds to the first imaging mode, the second intensity signal 925.2 corresponds to the second imaging mode and the third intensity signal 925.3 corresponds to the third imaging mode. The collected backscattered electron signal intensity reaches a maximum intensity 929.2 with the second imaging mode. In the second imaging mode, however, a large topography effect is overlaid over the material contrast between the backscattered electron intensity of substrate 51 and layer 53. The topography effect is even enhanced in the first imaging mode, where in the shadow region the backscattered intensity vanishes almost completely and a minimum 927.1 of the backscattered electron intensities almost reaches zero intensity. The minimum backscattered electron intensity depends on the sidewall angle 55 (see FIG. 5A) and can be used as a measure to determine the sidewall angle 55. In the third imaging mode, the topography effect due to the shadowing is reduced to a minimum and the detected backscattered electron intensity 925.3 can be overlaid by a signal corresponding to a slope angle of the layer edge or corresponding to the apparent width of the sidewall. The minimum intensity 927.3 of the third imaging mode is significantly larger and can vanish completely for large deviations of the slope angle from 90°. The minimum position Mx3 can be slightly shifted with respect to the minimum positions of for example the second intensity 925.2 at x=0. The minimum position Mx3 also depends on the sidewall angle. The extension of the shadow regions dx1, dx2 and dx3 are significantly different for the three imaging modes.

The selection of the imaging modes according to step 2 can be performed for according to a priori information, for example from the orientation of the layer edge or layer step, from the expected slope angle of the layer edge. The a priori information can be extracted from CAD information or from previous measurements of the mask or wafer. In these cases, an automated selection of imaging modes can be obtained, for example based on CAD information. In other scenarios, a first image can be obtained and analyzed. Thereby, a layer orientation and a topography effect are determined. According to the result of the analysis, a set of further imaging modes can be derived automatically. As a third option, a set of imaging modes can be selected via a user interface configured for a user input. In a fourth option, the selection is performed in a default mode, wherein for example at least four imaging modes with two deflection actions of the deflection unit 1603 in each of the px and py-directions is performed. Optionally, a fifth imaging mode with a focusing action of the lens 1605 or further actions is included in the set of default imaging modes.

According to step 6, the set of J intensities I(j) according to the set of J imaging modes is evaluated and a position of a layer edge 57 and a slope angle 55 of a layer edge are determined. In a first example, the determination is obtained analytically from different values of the set of J recorded intensities, for example from the width of the shadowing regions dx (j), the minimum intensity values min(j) (reference numbers 927.1 to 927.3 of FIG. 13) and the minimum intensity positions Mx(j). It is also possible to evaluate slope angles of the intensities, for example the slope dI(3) corresponding to the tangent line 935.3 of the intensity according to the third imaging mode at the position of the expected layer edge 57. Further values can be the maximum intensity values max (j) (corresponding to the reference numbers 929.1 to 929.3 of FIG. 13) and the intensity values of the substrate (left to the topographic effects, see reference numbers 933.1 to 933.3 in FIG. 13) of the intensities (reference numbers 925.1 to 925.3 in FIG. 13) for each imaging mode. The values can be compared to typical values of layer edges obtained from reference measurements or to simulation results. In a second example, the measured values for dx(j), Mx(j), the slopes dI(j), the maximum values Max(j) and the minimum values Min(j), and further parameters can be used in a model-based simulation according to for example a geometrical model with the edge position and slope angle as model parameters. In a third example, the set of J intensities I(j) can be analyzed with a machine learning algorithm, which is trained by several sets of reference intensities obtained from a plurality of training images of layer edges. The training intensities can be obtained by measurements of calibrated reference objects, or by simulations, for example Mont Carlo simulations of models with known structural parameters. Each measurement result with verified structural parameters can continuously be added to the training data and the machine learning algorithm can be modified and improved on the fly.

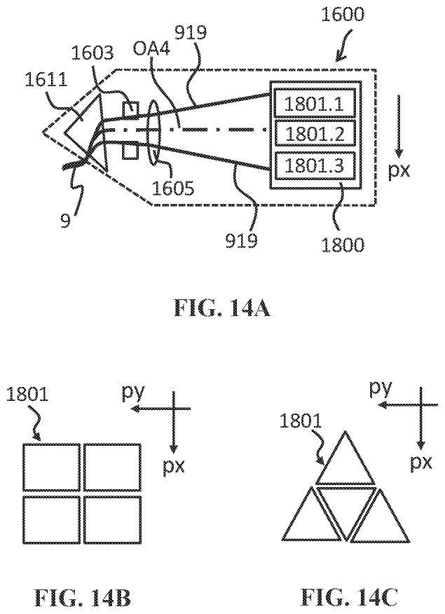

In the method described above, the image intensities according to the different imaging modes are obtained sequentially with a sequence of image scans. It is however also possible to obtain the different image intensities within one image scan, wherein the different imaging modes are sequentially performed at each dwell point 5 during an image scan. In such an example, the actuators of the detection unit 1600, for example deflector 1603 or lens 1605 are preferably fast electrostatic elements. Another example according to the invention in described in FIGS. 14A to 14C, in which the different imaging modes can be obtained in parallel in one image scan by utilizing an electron detector 1800 comprising several detector segments 1801. As shown in FIG. 14A, the detection unit 1600 according to another example of the invention comprises a detector 1800 with N detector segments 1801.1 to 1801.N. Some examples of arrangements of detector segments 1801 are illustrated in FIGS. 14B and 14C, for example a quadrant detector arrangement in FIG. 14B or an arrangement of 4 triangular detector segments in FIG. 14C. The number of detector segments is however not limited to three or four, but can be larger than four, for example seven hexagonal detector segments or nine quadratic detector segments. Each detector segment can comprise for example a scintillator and an Avalanche diode, but other detectors are possible as well. With each detector segment 1801.j, a different segment of the angular spectrum of the backscattered electrons is detected within one image scan, similar to the intensities according to the first and third imaging mode described above. With a moderate number K of detector segments between for example below K<=9, a topography signal can be extracted with sufficient signal to noise ratio from the K intensity signals. The signal to noise ration can further be improved by addition or averaging of some of the K intensity signals depending on the orientation of the topography signal corresponding for example to an orientation of a layer edge 57. The methods of imaging acquisition with different imaging modes with several detector segments as described in the example of FIGS. 14A to 14C can also be combined with actions of the deflection unit 1603, the focusing lens 1605 or the energy filter 1607. The energy filter has been omitted in FIGS. 8B, 9 and 12A, but can be nevertheless present in any example of the detection unit 1600. With the additional deflection or focusing action or different modes of energy filtering, more details of a topography information can be generated and extracted.

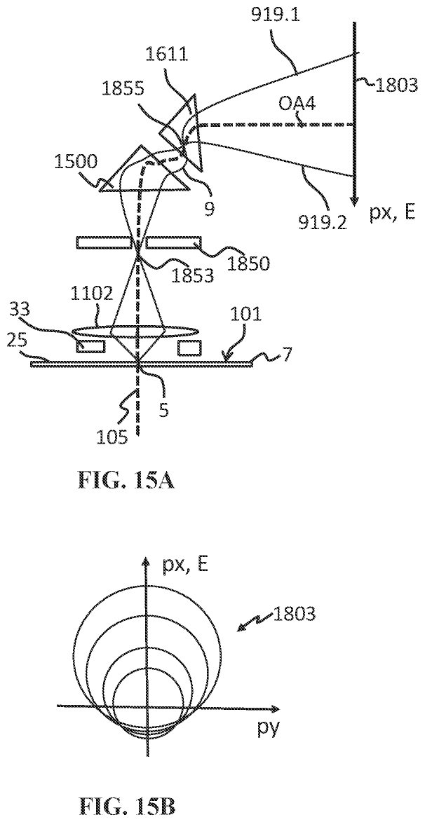

With the method of the detection of at least two segments of the angular spectrum of a backscattered electron beam 9 by image acquisition with at least two imaging modes of a detection unit 1600 of a corrected electron microscope CSEM, topography information can be separated from material contrast and a determination of a layer edge or layer slope can be extracted with high resolution of for example below 1 nm or even below 0.5 nm. The at least two segments of the angular spectrum can be obtained in a first example by a detector segment of limited acceptance angle in combination with a backscattered electron beam deflector 1603 or a backscattered electron beam focusing lens 1605. In a second example, the at least two segments of the angular spectrum are obtained by at least a first and a second detector segment. The selection of the at least two segments of the angular spectrum can be enhanced by a further energy cut off filter 1607. In a third embodiment of the invention, the separation of a topography information from a material contrast and the determination of a layer edge or layer slope is further improved by the dispersing element 1611 of the detection unit 1600. In FIGS. 15A and 15B, an effect of the dispersing unit 1611 and a method of extraction of topography information according to a third embodiment of the invention is described. Similar elements shown in FIG. 7 are illustrated with the same reference number. From a dwell point 5 on the surface 25 of a mask or wafer 7, backscattered electrons are generated and accelerated by the immersion field generated between sample 7 and electrode 33. The backscattered electron beam 9 is collected by the objective lens 1102 and a first intermediate cross over 1853 is formed. At or close to the first cross over 1853, an aperture 1850 can be located. The backscattered electron beam 9 passes the beam divider 1500 and forms a second cross over 1855 at the entrance of the dispersing unit 1611. Both cross overs 1853 and 1855 might not be single points for all backscattered electron trajectories but are rather distributed over a larger volume inside the aperture stop 1850 or in the proximity of the dispersing unit 1611. The backscattered electron beam 9 is limited by two maximum collection angles, for which the electron trajectories 919.1 and 919.2 are shown. With the parameters of the dispersing unit 1611, an energy separation of the backscattered electron beam 9 can be achieved. The result of an energy separation of the backscattered electron beam 9 is illustrated in FIG. 15B. The backscattered electron beam 9 in the detection plane 1803 is distributed according to the angular spectrum in px and py-direction and the energy spectrum parallel to the px-direction, wherein the backscattered electrons of larger momentum and larger propagation angle typically have a larger energy. Those backscattered electrons at larger angles, corresponding to larger circles in FIG. 15B, are therefore more deflected by the dispersing unit 1611 in direction of positive kinetic energy E. FIG. 15B illustrates one example of the deflection according to backscattered electron energy. Other scenarios of different deflection of specific kinetic energies are possible as well.

The methods of image acquisition described in the second embodiment can be applied as well in combination with the third embodiment. At least two segments of the mixed angular and energy spectrum are obtained, for example by at least two detector segments 1801.1 and 1801.2 or any of the imaging modes involving a deflection action of the deflector 1603 or focusing action of the lens 1605. The selection of the at least two segments of the mixed angular and energy spectrum can be enhanced by a further energy cut off filter 1607. The combination of a predetermined amount of energy dispersion with the angular spectrum distribution also allows a dedicated selection of backscattered electrons with maximum significance to topography effects. The selection of the at least two segments of the mixed energy- and angular spectrum can be obtained for example by optimization, for example by standard least square optimization or by a machine learning algorithm. For example, with a Monte Carlo simulation at a model object, the at least two segments of the mixed energy- and angular spectrum with maximum significance to the model parameters of interest can be determined. The intensity according to the imaging modes corresponding to the at least two segments of the mixed energy- and angular spectrum can be used as a training data set for a machine learning algorithm, which can later be applied in a precise measurement for mask or wafer inspection, mask repair or circuit edit applications.

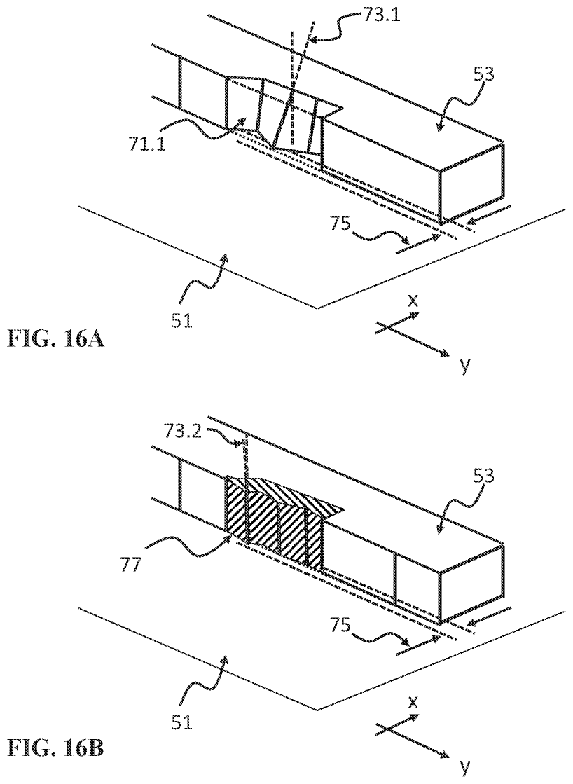

FIGS. 16A and 16B illustrate a fourth embodiment of the invention. FIG. 16A illustrates a mask repair operation at the high precision achievable with the apparatus of the first embodiment of the invention according to any of the methods of the second or third embodiment. In a first step illustrated at FIG. 16A, a mask defect 71.1 in an absorber line 53 on a substrate layer 51 is determined with high precision. With the apparatus and the methods described above, a precise determination of the extension of the defect 71.1 is determined, including at least a slope angle 73.1 of the defect 71.1. From the at least two intensities of a backscattered electron image according to the at least two imaging modes, and with the low energy imaging of the corrected electron microscope 1, the position, a deviation to a target range 75 of the edge position and the extensions of the defect can be determined with an accuracy below 1 nm, preferably even below 0.5 nm. The missing volume of material to be deposited in a repair operation can be determined with high accuracy. In the repair step illustrated at FIG. 16B, utilizing for example low energy electron beam assisted deposition of material from precursor gases provided by the apparatus 1000, the defect 71.1 is filled with for example chromium, forming the repaired defect 77. The performance of the repair operation is then verified by the apparatus of the first embodiment of the invention according to any of the methods of the second or third embodiments. A resulting edge position of the line 53 and a slope angle 73.2 of the line edge can be obtained with high accuracy. Thereby it is maintained that a repair operation is performed very well within the specification requirement for masks, including the strong requirements for EUV masks with edge positions below 0.5 nm or even less. The steps of repair and verification can also be performed iteratively. Of course, the fourth embodiment is not limited to missing material in a mask layer but can also be applied in analogy to the removal of excess material in mask layer. Further, the fourth embodiment is not limited to mask repair, but also to circuit edit operations at processed wafers. In both examples, layer material is removed by electron beam induced etching or deposited by electron beam induced deposition, and an end-pointing of the processing with high precision is required.

The invention is generally applicable to scanning electron microscopes with a beam dividing unit, separating incoming primary and outcoming backscattered electron beam. Ideally, the beam dividing unit is a corrected imaging system, which preserves the angular spectrum distribution of the backscattered electron beam. In a first example, an adjustment system of the detection unit in combination with at least a first finite detector aperture allows to dynamically adjust the detector acceptance angle without moving parts. The adjustment system comprises at least one of the deflection unit, an adjustable lens, an energy filter, or a dispersing unit, by which a backscattered electron distribution can be deflected and filtered. The adjustment system allows the operation of a high-resolution, low energy electron microscope in different imaging modes, for example in a first mode with a homogeneous illumination of the aperture and thereby suppressing topography effects or in at least a second mode using different parts of the backscattered electron angular distribution to analyze an edge of a layer. With the additional adjustable lens, in a further imaging mode the acceptance angle can be adjusted to achieve optimal material contrast. By adjusting the detector acceptance angle, it is for example possible to adjust and reduce the shadow width generated by a layer edge. In a second example, a segmented or 2D detector comprises at least a second detector with at least a second finite detector aperture, which is used to collect at least a second backscattered electron signal of a different range of the energy or momentum spectrum of the backscattered electrons. According to the invention, two or more images with different imaging modes are either obtained in sequence by using the adjustment unit or in parallel by using a first and at least a second detector element. With selective access to the momentum distribution of the backscattered electrons which is scattered almost parallel to the surface of the sample, more information on the structure of the surface, e.g., the sidewalls of layer edges, can be obtained.

The invention allows to work with a larger acceptance angle and select at least one appropriate segment of the angular spectrum and/or energy spectrum of backscattered electrons to record and analyze topography and material contrast of a surface of a sample in parallel. It is further possible to extract topographic information and to derive for example a height map, a slope edge of a layer or an edge position from a single scan with a low energy primary electron beam of a corrected electron microscope, utilizing low landing energies of below 400 eV, especially below 200 eV or even below 50 eV and thus allowing high precision and accuracy of below few nm, for example below 2 nm or even less. With an appropriate segment of the angular spectrum and/or energy spectrum of backscattered electrons, a material contrast can be separated from the topography or shadowing effects using suitable models. The models could be analytic, or phenomenological. A height and material map of the sample can then be computed. The models can for example be generated by Monte Carlo simulations and compared to experimental results. The selection of the appropriate segment of the angular spectrum and/or energy spectrum of backscattered electrons can be based on a priori information about for example a layer edge and a material composition. By taking two or more images with different imaging modes corresponding to different acceptance angles, the material contrast can be separated from the topography or shadowing effects with even higher precision, or even with less or without a priori information.

The invention thus offers a low energy electron microscope capable of selecting angular spectrum and/or energy of the backscattered electrons. With a priori knowledge of mask materials and general structure, slopes and positions of layer edges can be measured with high precision and an end-pointing of mask repair processes or circuit edit processes is enabled with high precision below few nm, for example below 2 nm or even below.

### LIST OF REFERENCE NUMBERS

1 corrected electron microscope
3 primary electron beam
5 Interaction area
7 sample; wafer or mask
9 backscattered electrons
12 backscattered electrons parallel to optical axis
14 backscattered electrons at medium angle
backscatter angular distribution
16 backscattered electrons at large angle
17 acceptance angle
19 effective collection angle
21 shadowing angle
25 surface of sample
27 momentum distribution of elastically backscattered electrons
31 grid electrode
33 electrode
35 liner tube
41 scanning direction
51 substrate or lower layer
53 absorber layer
55 slope angle
57 edge
61 medium EHT signal
63 low EHT signal
67 increased topography signal
71 defect
73 slope angle of defect
75 target range of edge position
77 repaired defect
150 gas storage containers
152 gas nozzles
154 control valve
500 Stage
603 deflection action
605 focusing action
607 deflection action
800 Control system
810 scanning and focusing control unit
840 control unit for primary beam forming unit
850 stage controller
860 detection control unit
880 Image acquisition unit
919 collection aperture of backscattered electrons
921 backscattered electron corresponding to shadow angle 21
925 effective detected backscattered electrons in first imaging mode
927 minimum of backscattered electron intensity
929 maximum of backscattered electron intensity
931 collection angle of first detector element
933 intensity value of substrate
935 slope of intensity curve at layer edge
1000 apparatus for mask repair
1020 deflection elements
1025 imaging elements
1035 ion gun
1080 Laser
1082 Laser beam
1085 suction device
1087 vacuum pump
1090 vacuum chamber
1100 primary beam focusing unit
1102 objective lens
1104 coil
1106 yoke
1108 axial gap
1110 scanning deflector
1113 lower pole piece
1115 upper pole piece
1121 first multipole corrector
1123 second multipole corrector
1301 particle beam generator
1400 corrected beam forming unit
1403 first condenser lens
1405 second condenser lens
1407 first deflection unit
1409 third condenser lens
1411 second deflection unit
1413 third deflection unit
1415 electrostatic mirror
1500 beam divider unit
1600 Detection Unit
1603 fifth deflection unit
1605 lens
1607 energy filter
1611 dispersion unit
1613 aperture stop
1800 electron detector
1801 detector segment
1803 detection plane
1850 aperture
1853 first cross over
1855 second cross over

What is claimed is:

1. An apparatus for inspection, repair or editing of a mask or wafer, comprising:
a beam forming unit, configured for generating during use a corrected primary charged particle beam;
a primary beam focusing unit for focusing during use the corrected primary charged particle beam onto a surface of a sample at a low landing energy LE and for collecting during use a backscattered electron beam comprising electrons which are scattered at large angles from the surface of the sample;
a detection unit with at least a first confined detector segment for detecting backscattered electrons;
a beam dividing unit for guiding during use the corrected primary charged particle beam from the beam forming unit to the primary beam focusing unit and for guiding the backscattered electron beam from primary beam focusing unit to the detection unit; and
a control unit connected to the detection unit and configured to perform an inspection task of a segment of the surface of the sample;
wherein the detection unit is configured to selectively detect at least a first selected segment of the angular spectrum of the backscattered electron beam with the at least first confined detector segment to generate at least a first detection signal I1.

2. The apparatus of claim 1, wherein the primary beam focusing unit, the beam dividing unit and the detection unit are configured to collect and image during use the backscattered electron beam including an axial segment of the angular spectrum of the backscattered electron beam, which propagates parallel and in opposite direction to the corrected primary charged particle beam.

3. The apparatus of claim 1, wherein the detection unit is further configured to selectively detect a second selected segment of the angular spectrum of the backscattered electron beam to generate at least a second detection signal I2, and wherein the second selected segment of the angular spectrum is different from the first selected segment of the angular spectrum of the backscattered electron beam.

4. The apparatus of claim 1, wherein the detection unit comprises at least an adjustment element, wherein the control unit is configured to control the adjustment element to selectively detect the at least first and/or second signals I1 and/or I2.

5. The apparatus of claim 4, wherein the adjustment element comprises at least one of a deflection unit configured for deflecting the backscattered electron beam, a focusing lens configured for focusing the backscattered electron beam, an adjustable energy filter or an adjustable dispersing unit.

6. The apparatus of claim 3, wherein the control unit is configured to select a single, off axis segment of the angular spectrum and to perform the inspection task with the single off axis segment of the angular spectrum.

7. The apparatus of claim 3, wherein the control unit is configured to sequentially adjust the detection unit in a first imaging mode to collect the first signal I1 and to adjust the detection unit in a second imaging mode to collect the second signal I2 in a subsequent second image scan across the surface of the sample.

8. The apparatus of claim 3, wherein the detection unit comprises a second confined detector segment to generate during use the second detection signal I2 corresponding to a second selected segment of the angular spectrum of the backscattered electron beam in a single image scan across the surface of the sample.

9. The apparatus of claim 8, wherein the detection unit further comprises at least an adjustment element, wherein the control unit is configured to control the adjustment element to selectively detect the at least first and second selected segment of the angular spectrum of the backscattered electron beam.

10. The apparatus of claim 1, wherein the control unit selects the at least first and/or second selected segment of the angular spectrum of the backscattered electron beam based on predetermined information about a structure on the surface of the sample.

11. The apparatus of claim 1, wherein the beam forming unit and the primary beam focusing unit are configured to focus the corrected primary electron beam on the surface of the sample with low kinetic energy of the primary electrons below 400 eV.

12. The apparatus of claim 1, wherein the primary beam focusing unit is configured to collect backscattered electrons at large angles exceeding 0.7 rad from the normal of the surface of the sample.

13. The apparatus of claim 1, wherein the at least first selected segment of the angular spectrum of the backscattered electron beam is selected to generate a first detection signal I1 with a reduced sensitivity to the topography of the segment of the surface.

14. The apparatus of claim 13, wherein the second selected segment of the angular spectrum of the backscattered electron beam is selected to generate a second detection signal I2 with an increased sensitivity to the topography of the segment of the surface.

15. The apparatus of claim 1, further comprising a plurality of gas nozzles for providing a plurality of process gases to a surface of a sample; and wherein the control unit is configured to perform during use at least one of an electron beam assisted deposition or electron beam assisted etching operation.

16. The apparatus of claim 1, wherein the control unit is further configured to initiate or terminate an electron beam assisted repair or editing process based on the at least a first detection signal I1 and/or second detection signal I2.

17. A method of inspection, repair or circuit edit of a mask or wafer, comprising the steps of:
a) alignment of an inspection site of a mask or wafer in an image plane of a low-energy electron microscope;
b) selecting at least a first imaging mode and a second imaging mode suitable for a detection and an extraction of topography effects, and for separation of topography effects from a material contrast of the surface segment of the mask or wafer at the inspection site;
c) performing a first image scan with low landing energies of a primary electron beam in the first imaging mode to acquire a first image signal;
d) performing a second image scan with low landing energies of the primary electron beam in the second imaging mode to acquire a second image signal; and
e) analyzing the first and second image signals to derive a topography information and a material composition of the surface segment of the mask or wafer at the inspection site.

18. The method of claim 17, wherein step c) further comprises:
generating a first signal to drive an adjustment element of a detection unit; and
deflecting and/or focusing the backscattered electron beam to detect a first selected segment of the angular spectrum of the backscattered electron beam in the first imaging mode.

19. The method of claim 17, wherein step d) further comprises:
generating a second signal to drive an adjustment element of a detection unit; and
deflecting and/or focusing the backscattered electron beam to detect a second selected segment of the angular spectrum of the backscattered electron beam in the second imaging mode.

20. The method of claim 17, further comprising the determination of at least one of a minimum intensity, a maximum intensity, a width or extension of a shadow region dx, a minimum intensity position Mx, and/or a slope of an image signal at layer edge; or a difference of at least one of the values above between the first and second image signal.

21. The method of claim 17, further comprising the determination of at least one of an edge position of a layer edge; a feature dimension; an edge roughness; an edge slope; or a micro-defect with an accuracy below 2 nm.

22. The method of claim 21, further comprising the application of a machine learning algorithm with a set of training or reference data corresponding to at least one of an edge position of a layer edge; a feature dimension; an edge roughness; an edge slope; or a micro-defect.

23. The method of claim 17, further comprising the step of receiving predetermined information about the inspection site of the mask or wafer; and wherein the selecting of at least a first imaging mode and a second imaging mode is performed according to the predetermined information.

24. The method of claim 17, further comprising the step of determining and storing the at least first and second imaging modes suitable for a detection and an extraction of topography effects, and for separation of topography effects from a material contrast of the surface segment of the mask or wafer at the inspection site.

25. The method of claim 24, wherein the step of determining the at least first and second imaging modes comprises the steps of:
performing a sequence of at least two image scans with low landing energies of a primary electron beam, each with a different selected segment of the angular spectrum of the backscattered electron beam at the inspection site; and
determining at least first and second imaging modes from the sequence of image scans; and
storing at least first and second imaging modes for a subsequent similar inspection site.

26. The method of claim 24, wherein the determining of the at least first and second imaging modes suitable for a detection and an extraction of topography effects, and for separation of topography effects from a material contrast of the surface segment of the mask or wafer at the inspection site is performed according to a machine learning algorithm using a plurality of training or reference image signals.

27. The method of claim 17, further comprising the step of initiating or terminating an electron beam assisted repair or editing process.

28. A low energy electron microscope for investigating a surface of a sample with a corrected primary electron beam at a low landing energy LE, comprising:
a beam forming unit, configured for generating during use the corrected primary charged particle beam;
a primary beam focusing unit for focusing during use the corrected primary charged particle beam onto the surface of the sample and for collecting during use a backscattered electron beam comprising electrons which are scattered at large angles from the surface of the sample;
a detection unit with at least a first confined detector segment for detecting at least a first segment of the angular spectrum of the backscattered electron beam and for generating at least a first detection signal I1;
a beam dividing unit for guiding during use the corrected primary charged particle beam from the beam forming unit to the primary beam focusing unit and for guiding the backscattered electron beam including an axial segment of the angular spectrum of the backscattered electron beam, which propagates parallel and in opposite direction to the corrected primary charged particle beam, from the primary beam focusing unit to the detection unit; and
a control unit connected to the detection unit;
wherein the detection unit further comprises an adjustment element, and
wherein the control unit is configured to control the adjustment element to select in a first imaging mode the first selected segment of the angular spectrum of the backscattered electron beam.

29. The low energy electron microscope of claim 28, wherein the adjustment element comprises at least one of a deflection unit configured for deflecting the backscattered electron beam, a focusing lens configured for focusing the backscattered electron beam, an adjustable energy filter or an adjustable dispersing unit.

30. The low energy electron microscope of claim 28, wherein the control unit is configured to control the adjustment element to select an off-axis segment of the angular spectrum corresponding to backscattered electrons scattered at large angles from the surface of the sample.

31. The low energy electron microscope of claim 28, wherein the control unit is further configured to control the adjustment element to select in a second imaging mode a second selected segment of the angular spectrum of the backscattered electron beam, different from the first selected segment.

32. The low energy electron microscope of claim 31, wherein the control unit is further configured to sequentially perform a first image scan of a segment of the surface of the sample in the first imaging mode and perform a second image scan at the same segment of the surface in the second imaging mode.

33. The low energy electron microscope of claim 28, wherein the detection unit comprises a second confined detector segment to generate during use a second detection signal I2 corresponding to a second selected segment of the angular spectrum of the backscattered electron beam.

34. The low energy electron microscope of claim 28, wherein the beam forming unit and the primary beam focusing unit are configured to focus the corrected primary electron beam on the surface of the sample and to decelerate the primary electron beam before reaching the sample surface to kinetic energies below 400 eV.

35. The low energy electron microscope of claim 28, wherein the primary beam focusing unit is configured to collect backscattered electrons at large angles exceeding 0.7 rad from the normal of the surface of the sample.

36. The low energy electron microscope of claim 28, wherein the control unit is further configured to determine the at least first and second imaging modes suitable for a detection and an extraction of topography effects, and for separation of topography effects from a material contrast of the segment of the surface of the mask or wafer.

37. The low energy electron microscope of claim 28, wherein the control unit is further configured to determine at least one of an edge position of a layer edge; a feature dimension; an edge roughness; an edge slope; or a micro-defect; with an accuracy below 2 nm.

38. The low energy electron microscope of claim 28, further comprising an electrostatic mirror corrector.

39. A low energy electron microscope for investigating a surface of a sample with a corrected primary electron beam at a low landing energy LE, comprising:
a beam forming unit, configured for generating during use the corrected primary charged particle beam;
a primary beam focusing unit for focusing during use the corrected primary charged particle beam onto the surface of the sample and for collecting during use a backscattered electron beam comprising electrons which are scattered at large angles from the surface of the sample;
a detection unit with a first confined detector segment for detecting a first segment of the angular spectrum of the backscattered electron beam and for generating a first detection signal I1; and
a beam dividing unit for guiding during use the corrected primary charged particle beam from the beam forming unit to the primary beam focusing unit and for guiding the backscattered electron beam including an axial segment of the angular spectrum of the backscattered electron beam, which propagates parallel and in opposite direction to the corrected primary charged particle beam, from the primary beam focusing unit to the detection unit;
wherein the detection unit further comprises at least a second confined detector segment for detecting at least a second segment of the angular spectrum of the backscattered electron beam and for generating at least a second detection signal I2, different from the first signal I1.

40. The low energy electron microscope of claim 39, wherein the detection unit comprises a third confined detector segment to generate during use a third detection signal I3 corresponding to a third selected segment of the angular spectrum of the backscattered electron beam.

41. The low energy electron microscope of claim 39, wherein the beam forming unit and the primary beam focusing unit are configured to focus the corrected primary electron beam on the surface of the sample and to decelerate the primary electron beam before reaching the sample surface to kinetic energies below 400 eV.

42. The low energy electron microscope of claim 39, wherein the primary beam focusing unit is configured to collect backscattered electrons at large angles exceeding 0.7 rad from the normal of the surface of the sample.

43. The low energy electron microscope of claim 39, wherein the control unit is further configured to determine form the at least first and second detection signal I1 and I2 at least one of an edge position of a layer edge; a feature dimension; an edge roughness; an edge slope; or a micro-defect; with an accuracy below 2 nm.

44. The low energy electron microscope of claim 39, further comprising an electrostatic mirror corrector.
